(19) United States
(12) Patent Application Publication
(10) Pub. No.: US 2025/0374767 A1
(43) Pub. Date: Dec. 4, 2025

(54) DISPLAY DEVICE AND METHOD FOR MANUFACTURING THE SAME

(71) Applicant: Samsung Display Co., LTD., Yongin-si (KR)

(72) Inventors: Hyo Jeong KWON, Yongin-si (KR); Woo Yong SUNG, Yongin-si (KR); Hee Jun YANG, Yongin-si (KR); Soo Min OH, Yongin-si (KR)

(73) Assignee: Samsung Display Co., LTD., Yongin-si (KR)

(21) Appl. No.: 19/059,798

(22) Filed: Feb. 21, 2025

(30) Foreign Application Priority Data
May 31, 2024 (KR) 10-2024-0071686
Jun. 18, 2024 (KR) 10-2024-0078648

(51) Int. Cl. H10K 59/122; H10K 59/12; H10K 59/80; H10K 102/10

(52) U.S. Cl. CPC H10K 59/122; H10K 59/1201; H10K 59/80522; H10K 59/873; H10K 2102/101

(57) ABSTRACT

A display device includes a bank layer disposed on an emission area of a substrate and comprising at least one metal layer; a pixel defining layer disposed on the bank layer and defining an opening; and a light-emitting element disposed on the pixel defining layer and comprising a light-emitting layer, a cathode electrode, and an auxiliary electrode. The bank layer includes a first side surface facing a non-emission area of the substrate; and a tip portion protruding further toward the non-emission area than the first side surface. A portion of the tip portion of the bank layer facing the non-emission area is inclined in a direction intersecting the substrate.

### CROSS-REFERENCE TO RELATED APPLICATION

This application claims priority to and benefits of Korean Patent Application No. 10-2024-0071686 filed on May 31, 2024 and No. 10-2024-0078648 filed on Jun. 18, 2024 under 35 U.S.C. § 119, in the Korean Intellectual Property Office, the entire contents of which are incorporated herein by reference.

### BACKGROUND

### 1. Technical Field

The disclosure relates to a display device having improved electrical characteristics and a method for manufacturing the same.

### 2. Description of the Related Art

The importance of display devices as communication media, has been emphasized because of the increasing developments of information technology. For example, display devices are used in various electronic devices such as smartphones, digital cameras, laptop computers, navigation devices, and smart televisions. The display devices may be flat panel display devices such as liquid crystal display devices, field emission display devices, and organic light-emitting display devices. Since each of pixels of a display panel includes a light-emitting element capable of emitting light independently of a separate light source, the light-emitting display device may display an image.

Glass-type display devices have been increasingly used in virtual reality and augmented reality. The glass-type display devices are very small, for example 2 inches or less, and have a high pixel pitch with high resolution. For example, the display device may have a high pixel pitch of 1,000 pixels per inch (PPI) or greater.

Since the size of an emission area of the light-emitting element in the display device of a very small size or a high pixel pitch, light-emitting elements are desirable to be separated for each emission area by a mask process.

It is to be understood that this background of the technology section is, in part, intended to provide useful background for understanding the technology. However, this background of the technology section may also include ideas, concepts, or recognitions that were not part of what was appreciated by those skilled in the pertinent art prior to a corresponding effective filing date of the subject matter disclosed herein.

### SUMMARY

Embodiments provide a display device having improved electrical characteristics.

Embodiments also provide a method for manufacturing the display device.

However, embodiments of the disclosure are not limited to those set forth herein. The above and other embodiments will become more apparent to one of ordinary skill in the art to which the disclosure pertains by referencing the detailed description of the disclosure given below.

According to an aspect of the disclosure, a display device includes a bank layer disposed on an emission area of a substrate and comprising at least one metal layer; a pixel defining layer disposed on the bank layer and defining an opening; and a light-emitting element disposed on the pixel defining layer and comprising a light-emitting layer, a cathode electrode, and an auxiliary electrode. The bank layer includes a first side surface facing a non-emission area of the substrate; and a tip portion protruding further toward the non-emission area than the first side surface. A portion of the tip portion of the bank layer facing the non-emission area is inclined in a direction intersecting the substrate.

In an embodiment, the pixel defining layer may overlap the emission area in a plan view, and a portion of the pixel defining layer in contact with the tip portion of the bank layer may be inclined in the direction intersecting the substrate.

In an embodiment, the tip portion of the bank layer may include a first surface in contact with the pixel defining layer, a second surface opposite to the first surface, and a second side surface connecting the first surface and the second surface, and the second surface may be inclined by a first angle with respect to a reference line parallel to the substrate.

In an embodiment, the first angle may be greater than or equal to about 0.1 degrees.

In an embodiment, a height of the tip portion of the bank layer may be less than or equal to about 2000 angstroms.

In an embodiment, the auxiliary electrode entirely may cover the cathode electrode, and the auxiliary electrode may be in contact with the second surface and the second side surface of the bank layer.

The cathode electrode may be electrically connected to the bank layer by the auxiliary electrode.

In an embodiment, the auxiliary electrode may cover the tip portion of the bank layer.

In an embodiment, the bank layer may include a first bank layer, a second bank layer, and a third bank layer which are sequentially stacked, and the second bank layer and the third bank layer may contain different materials from each other.

In an embodiment, the second bank layer may contain aluminum, and the third bank layer may contain titanium.

In an embodiment, the third bank layer may include a tip portion protruding further toward the non-emission area than the second bank layer.

In an embodiment, the pixel defining layer may include a first pixel defining layer in contact with the bank layer; and a second pixel defining layer disposed on the first pixel defining layer and defining the opening.

In an embodiment, the first pixel defining layer may include a first surface in contact with the second pixel defining layer and a second surface opposite to the first surface. In a portion of the first pixel defining layer overlapping the tip portion of the bank layer in a plan view, portions of the first surface and the second surface may be inclined in the direction intersecting the substrate.

In an embodiment, the light-emitting layer may completely cover the second pixel defining layer and may be in contact with a portion of the first pixel defining layer.

In an embodiment, the display device may further include an encapsulation layer disposed on the light-emitting element. The encapsulation layer may be in contact with the bank layer, and may fill an undercut portion formed by the first side surface of the bank layer and the tip portion of the bank layer.

According to an aspect of the disclosure, a method for manufacturing a display device includes forming a plurality of sacrificial layers on a substrate; forming a bank layer covering the plurality of sacrificial layers and a first pixel defining layer covering the bank layer; forming an anode electrode on the first pixel defining layer; forming a second pixel defining layer covering an edge of the anode electrode; removing the second pixel defining layer, the first pixel defining layer, the bank layer not overlapping the anode electrode in a plan view, and the plurality of sacrificial layers; and forming a light-emitting layer, a cathode electrode, and an auxiliary electrode on the anode electrode. In the removing of the sacrificial layer, the bank layer is formed with a tip portion protruding further than a side surface of the bank layer, and an edge of the tip portion of the bank layer is inclined toward the first pixel defining layer.

In an embodiment, in the removing of the sacrificial layer, an edge of the first pixel defining layer and the bank layer may be inclined in a same direction.

In an embodiment, in the forming of the first pixel defining layer, the first pixel defining layer may have tensile stress, and in the forming of the light-emitting layer, the light-emitting layer may be formed by a photo-pattern process.

According to an aspect of the disclosure, an electronic device includes at least one display device comprising a substrate comprising an emission area and a non-emission area; and a display device housing accommodating the at least one display device. The at least one display device includes a bank layer disposed on the emission area of the substrate and comprising at least one metal layer; a pixel defining layer disposed on the bank layer and defining an opening; and a light-emitting element disposed on the pixel defining layer and comprising a light-emitting layer, a cathode electrode, and an auxiliary electrode. The bank layer includes a first side surface facing the non-emission area; and a tip portion protruding further toward the non-emission area than the first side surface. A portion of the tip portion of the bank layer facing the non-emission area is inclined in a direction intersecting the substrate.

In an embodiment, the display device may further include a via layer disposed between the substrate and the bank layer. The via layer may have a convex shape in the direction intersecting the substrate, and the bank layer and the pixel defining layer may cover a lower structure along a shape of the via layer.

The bank layer may overlap the via layer in the direction intersecting the substrate.

According to the display device and the method for manufacturing the display device according to an embodiment, the display device may include light-emitting elements spaced apart from each other in each emission area without using a separate fine metal mask and simultaneously provided with an increased contact area between a cathode electrode and a bank structure.

However, effects according to the embodiments of the disclosure are not limited to those above and various other effects are incorporated herein.

### BRIEF DESCRIPTION OF THE DRAWINGS

An additional appreciation according to the embodiments of the disclosure will become more apparent by describing in detail the embodiments thereof with reference to the accompanying drawings, wherein:

FIG. 1 is a schematic perspective view illustrating a head mounted electronic device according to an embodiment;

FIG. 2 is a schematic exploded perspective view of the head mounted electronic device of FIG. 1;

FIG. 3 is a schematic perspective view illustrating a head mounted electronic device according to an embodiment;

FIG. 4 is a schematic exploded perspective view showing the display device 10 according to an embodiment;

FIG. 5 is a schematic cross-sectional view of the display panel of an embodiment taken along line X1-X1′ of FIG. 4;

FIG. 6 is a schematic enlarged cross-sectional view of the light-emitting element layer overlapping the first emission area in FIG. 5 in a plan view;

FIG. 7 is a schematic enlarged cross-sectional view of area T in FIG. 6;

FIG. 8 is a schematic enlarged cross-sectional view of a light-emitting element layer according to an embodiment overlapping the first emission area in FIG. 5 in a plan view;

FIG. 9 is a schematic enlarged cross-sectional view of a light-emitting element layer according to an embodiment overlapping the first emission area in FIG. 5 in a plan view;

FIGS. 10 to 22 are schematic cross-sectional views sequentially illustrating a manufacturing process of a light-emitting element layer of a display panel according to an embodiment;

FIG. 23 is a schematic cross-sectional view of a display panel according to an embodiment taken along line X1-X1′ in FIG. 4;

FIG. 24 is a schematic enlarged cross-sectional view of the light-emitting element layer overlapping the first emission area in FIG. 23 in a plan view;

FIG. 25 is a schematic enlarged cross-sectional view of area Q in FIG. 24; and

FIGS. 26 to 36 are schematic cross-sectional views sequentially illustrating a manufacturing process of the light-emitting element layer of the display panel of FIG. 23.

### DETAILED DESCRIPTION OF THE EMBODIMENTS

In the following description, for the purposes of explanation, numerous specific details are set forth in order to provide a thorough understanding of various embodiments or implementations of the disclosure. As used herein “embodiments” and “implementations” are interchangeable words that are non-limiting examples of devices or methods disclosed herein. It is apparent, however, that various embodiments may be practiced without these specific details or with one or more equivalent arrangements. Here, various embodiments do not have to be exclusive nor limit the disclosure. For example, specific shapes, configurations, and characteristics of an embodiment may be used or implemented in another embodiment.

Unless otherwise specified, the illustrated embodiments are to be understood as providing features of the disclosure. Therefore, unless otherwise specified, the features, components, modules, layers, films, panels, regions, and/or aspects, etc. (hereinafter individually or collectively referred to as “elements”), of the various embodiments may be otherwise combined, separated, interchanged, and/or rearranged without departing from the scope of the disclosure.

The use of cross-hatching and/or shading in the accompanying drawings is generally provided to clarify boundaries between adjacent elements. As such, neither the presence nor the absence of cross-hatching or shading conveys or indicates any preference or requirement for particular materials, material properties, dimensions, proportions, commonalities between illustrated elements, and/or any other characteristic, attribute, property, etc., of the elements, unless specified. Further, in the accompanying drawings, the size and relative sizes of elements may be exaggerated for clarity and/or descriptive purposes. When an embodiment may be implemented differently, a specific process order may be performed differently from the described order. For example, two consecutively described processes may be performed substantially at the same time or performed in an order opposite to the described order. Also, like reference numerals and/or reference characters denote like elements.

When an element, such as a layer, is referred to as being “on,” “connected to,” or “coupled to” another element or layer, it may be directly on, connected to, or coupled to the other element or layer or intervening elements or layers may be present. When, however, an element or layer is referred to as being “directly on,” “directly connected to,” or “directly coupled to” another element or layer, there are no intervening elements or layers present. To this end, the term “connected” may refer to physical, electrical, and/or fluid connection, with or without intervening elements. Further, the axis of the first direction DR1, the axis of the second direction DR2, and the axis of the third direction DR3 are not limited to three axes of a rectangular coordinate system, such as the X, Y, and Z-axes, and may be interpreted in a broader sense. For example, the axis of the first direction DR1, the axis of the second direction DR2, and the axis of the third direction DR3 may be perpendicular to one another, or may represent different directions that are not perpendicular to one another. For the purposes of this disclosure, “at least one of A and B” may be construed as A only, B only, or any combination of A and B. Also, “at least one of X, Y, and Z” and “at least one selected from the group consisting of X, Y, and Z” may be construed as X only, Y only, Z only, or any combination of two or more of X, Y, and Z. As used herein, the term “and/or” includes any and all combinations of one or more of the associated listed items.

Although the terms “first,” “second,” etc. may be used herein to describe various elements, these elements should not be limited by these terms. These terms are used to distinguish one element from another element. Thus, a first element discussed below could be termed a second element without departing from the teachings of the disclosure.

Spatially relative terms, such as “beneath,” “below,” “under,” “lower,” “above,” “upper,” “over,” “higher,” “side” (e.g., as in “sidewall”), and the like, may be used herein for descriptive purposes, and, thereby, to describe one element's relationship to another element(s) as illustrated in the drawings. Spatially relative terms are intended to encompass different orientations of an apparatus in use, operation, and/or manufacture in addition to the orientation depicted in the drawings. For example, if the apparatus in the drawings is turned over, elements described as “below” or “beneath” other elements or features would then be oriented “above” the other elements or features. Thus, the term “below” can encompass both an orientation of above and below. Furthermore, the apparatus may be otherwise oriented (e.g., rotated 90 degrees or at other orientations), and, as such, the spatially relative descriptors used herein should be interpreted accordingly.

The terminology used herein is for the purpose of describing particular embodiments and is not intended to be limiting. As used herein, the singular forms, “a,” “an,” and “the” are intended to include the plural forms as well, unless the context clearly indicates otherwise. Moreover, the terms “comprises,” “comprising,” “includes,” and/or “including,” when used in this specification, specify the presence of stated features, integers, steps, operations, elements, components, and/or groups thereof, but do not preclude the presence or addition of one or more other features, integers, steps, operations, elements, components, and/or groups thereof. The terms “about” or “approximately” as used herein is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” may mean within one or more standard deviations, or within +30%, 20%, 10%, 5% of the stated value.

Various embodiments are described herein with reference to sectional and/or exploded illustrations that are schematic illustrations of embodiments and/or intermediate structures. As such, variations from the shapes of the illustrations as a result, for example, of manufacturing techniques and/or tolerances, are to be expected. Thus, embodiments disclosed herein should not necessarily be construed as limited to the particular illustrated shapes of regions, but are to include deviations in shapes that result from, for instance, manufacturing. In this manner, regions illustrated in the drawings may be schematic in nature and the shapes of these regions may not reflect actual shapes of regions of a device and, as such, are not necessarily intended to be limiting.

As customary in the field, some embodiments are described and illustrated in the accompanying drawings in terms of functional blocks, units, and/or modules. Those skilled in the art will appreciate that these blocks, units, and/or modules are physically implemented by electronic (or optical) circuits, such as logic circuits, discrete components, microprocessors, hard-wired circuits, memory elements, wiring connections, and the like, which may be formed using semiconductor-based fabrication techniques or other manufacturing technologies. In the case of the blocks, units, and/or modules being implemented by microprocessors or other similar hardware, they may be programmed and controlled using software (e.g., microcode) to perform various functions discussed herein and may optionally be driven by firmware and/or software. It is also contemplated that each block, unit, and/or module may be implemented by dedicated hardware, or as a combination of dedicated hardware to perform some functions and a processor (e.g., one or more programmed microprocessors and associated circuitry) to perform other functions. Also, each block, unit, and/or module of some embodiments may be physically separated into two or more interacting and discrete blocks, units, and/or modules without departing from the scope of the disclosure. Further, the blocks, units, and/or modules of some embodiments may be physically combined into more complex blocks, units, and/or modules without departing from the scope of the disclosure.

Unless otherwise defined or implied herein, all terms (including technical and scientific terms) used herein have the same meaning as commonly understood by those skilled in the art to which this disclosure pertains. It will be further understood that terms, such as those defined in commonly used dictionaries, should be interpreted as having a meaning that is consistent with their meaning in the context of the relevant art and the disclosure, and should not be interpreted in an ideal or excessively formal sense unless clearly so defined herein.

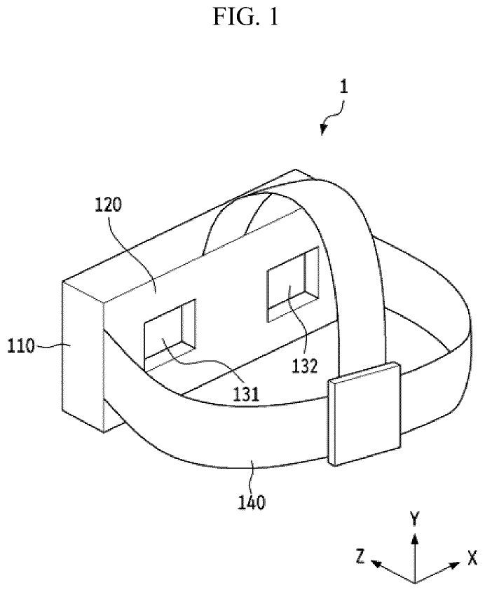

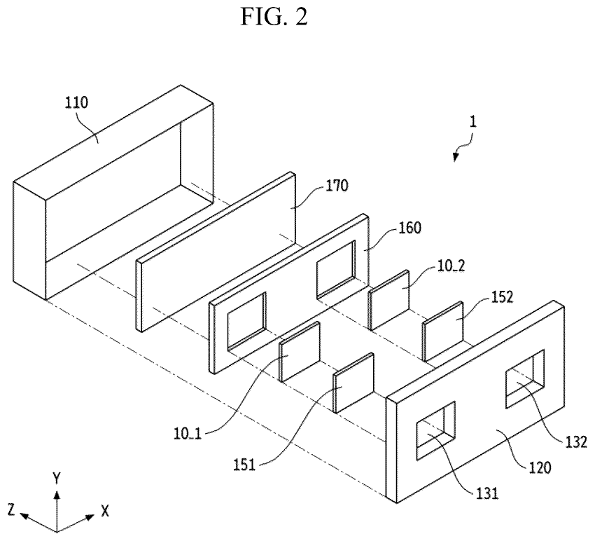

FIG. 1 is a schematic perspective view illustrating a head mounted electronic device according to an embodiment. FIG. 2 is a schematic exploded perspective view of the head mounted electronic device of FIG. 1.

Referring to FIGS. 1 and 2, a head mounted electronic device 1 according to an embodiment may include a display device 10, a display device housing 110, a housing cover 120, a first eyepiece 131, a second eyepiece 132, a head mounted band 140, a middle frame 160, a first optical member 151, a second optical member 152, and a control circuit board 170.

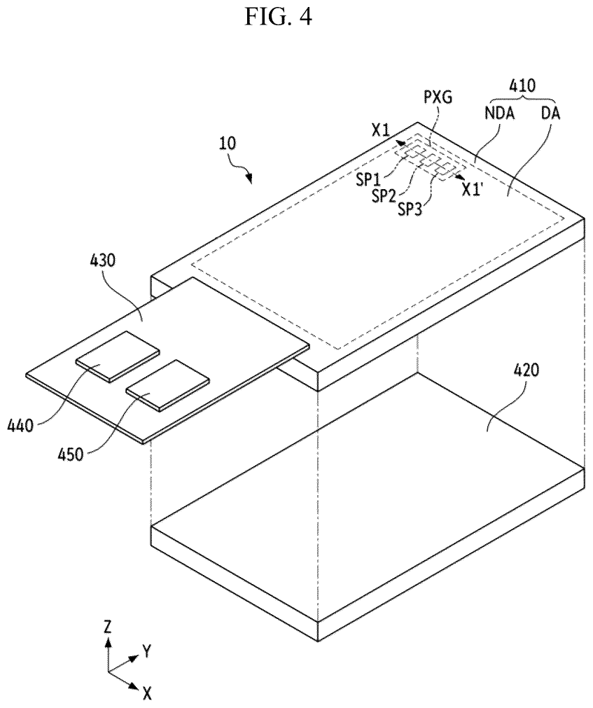

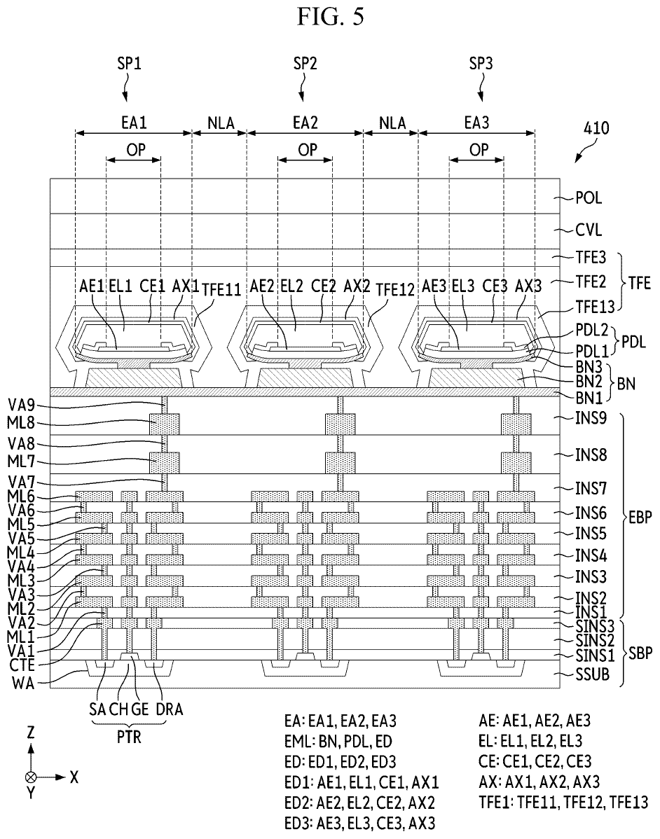

The display device 10 may include a first display device 10_1 and a second display device 10_2. The first display device 10_1 may provide (or display) an image to the user's left eye, and the second display device 10_2 may provide (or display) an image to the user's right eye. Detailed description of the display device 10 is provided below with reference to FIGS. 4 and 5.

The first optical member 151 may be disposed between the first display device 10_1 and the first eyepiece 131, and the second optical member 152 may be disposed between the second display device 10_2 and the second eyepiece 132. Each of the first optical member 151 and the second optical member 152 may include at least one convex lens.

The middle frame 160 may be disposed between the first display device 10_1 and the control circuit board 170, and may be disposed between the second display device 10_2 and the control circuit board 170. The middle frame 160 may support and fix (or hold) the first display device 10_1, the second display device 10_2, and the control circuit board 170. For example, the first display device 10_1, the second display device 10_2, and the control circuit board 170 may be fixed to the middle frame 160.

The control circuit board 170 may be disposed between the middle frame 160 and the display device housing 110. The control circuit board 170 may be electrically connected to the first display device 10_1 and the second display device 10_2 through the connector. The control circuit board 170 may convert an image (or an image source or an object to be taken in a video) inputted from the outside into digital video data, and transmit the digital video data to the first display device 10_1 and the second display device 10_2 through the connector.

The control circuit board 170 may transmit the digital video data corresponding to a left eye image optimized for a user's left eye to the first display device 10_1, and may transmit the digital video data corresponding to a right eye image optimized for a user's right eye to the second display device 10_2. In other embodiments, the control circuit board 170 may transmit a same digital video data to the first display device 10_1 and the second display device 10_2.

The display device housing 110 may accommodate the display device 10, the middle frame 160, the first optical member 151, the second optical member 152, and the control circuit board 170. The housing cover 120 may cover an opened surface of the display device housing 110. For example, the display device housing 110 and the housing cover 120 may be combined with each other, and form a space in which the display device 10, the middle frame 160, the first optical member 151, the second optical member 152, and the control circuit board 170 are disposed. The housing cover 120 may include the first eyepiece 131 on which the user's left eye is disposed and the second eyepiece 132 on which the user's right eye is disposed. In FIGS. 1 and 2, the first eyepiece 131 and the second eyepiece 132 may be disposed separately. However, the embodiment of the disclosure is not limited thereto. The first eyepiece 131 and the second eyepiece 132 may be integrated to each other.

The first eyepiece 131 may be aligned with the first display device 10_1 and the first optical member 151, and the second eyepiece 132 may be aligned with the second display device 10_2 and the second optical member 152. For example, the first display device 10_1 and the first optical member 151 may be disposed on the first eyepiece 131, and the second display device 10_2 and the second optical member 152 may be disposed on the second eyepiece 132. Therefore, a user may view the image of the first display device 10_1 magnified as a virtual image by the first optical member 151 through the first eyepiece 131, and may view the image of the second display device 10_2 magnified as a virtual image by the second optical member 152 through the second eyepiece 132.

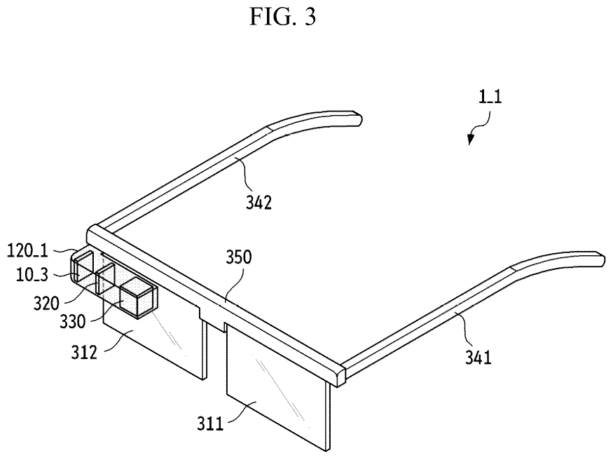

The head mounted band 140 may fix the display device housing 110 to a user's head, and the first eyepiece 131 and the second eyepiece 132 of the housing cover 120 may be disposed (or located) at a user's left eye and a user's right eye, respectively. For example, the first eyepiece 131 and the second eyepiece 132 of the housing cover 120 may maintain right positions on the user's left and right eyes by the head mounted band 140. In case that the display device housing 110 is disposed in a light and small device, the head mounted electronic device 1 may include an eyeglass frame, as shown in FIG. 3, instead of the head mounted band 140.

The head mounted electronic device 1 may further include a battery for supplying a power (e.g., an electrical power), an external memory slot capable of storing an external memory, an external connection port for receiving an image (e.g., an image source or an object to be taken in a video), and a wireless communication module. The external connection port may be a universe serial bus (USB) terminal, a display port, or a high-definition multimedia interface (HDMI) terminal, and the wireless communication module may be a 5G communication module, a 4G communication module, a Wi-Fi module, or a Bluetooth module. However, the disclosure is not limited thereto.

FIG. 3 is a schematic perspective view illustrating a head mounted electronic device according to an embodiment.

Referring to FIG. 3, a head mounted electronic device 1_1 according to an embodiment may be a glass-type electronic device in which a display device housing 120_1 is disposed in a light and small device. The head mounted electronic device 1_1 according to an embodiment may include the display device 10 (e.g., refer to FIG. 4), a left lens 311, a right lens 312, a support frame 350, temples 341 and 342, an optical member 320, an optical path changing member 330, and the display device housing 120_1.

The display device shown in FIG. 3 may include a third display device 10_3. The third display device 10_3 may be substantially the same as the first display device 10_1 and the second display device 10_2 shown in FIG. 2. Detailed description of the display device 10 is provided below with reference to FIGS. 4 and 5.

The display device housing 120_1 may include the display device (e.g., the third display device 10_3), the optical member 320, and the optical path changing member 330. The image displayed on the display device may be magnified by the optical member 320, have an optical path changed by the optical path changing member 330, and be provided to a user's right eye through the right lens 312. For example, light displaying the image may be generated by the third display device 10_3, and pass through the optical member 320, the optical path changing member 330, and the right lens 312, in sequence. Accordingly, the user may view an augmented reality image in which a virtual image displayed on the display device (e.g., the third display device 10_3) through the right eye and a real image seen through the right lens 312 are combined.

In FIG. 3, the display device housing 120_1 may be disposed at the right end of the support frame 350. However, the embodiment of the disclosure is not limited thereto. For example, the display device housing 120_1 may be disposed at the left end of the support frame 350, and the image of the display device 10 (e.g., refer to FIG. 4) may be provided to the user's left eye. In other embodiments, the display device housing 120_1 may be disposed at both the left end and the right end of the support frame 350, and the user may view the image displayed on the display device 10 through both the left eye and the right eye.

FIG. 4 is a schematic exploded perspective view showing the display device 10 according to an embodiment.

Referring to FIG. 4, the display device 10 according to an embodiment may be a device displaying a moving image or a still image. The display device 10 according to an embodiment may be applied to (or be included in) various electronic apparatuses, and the electronic apparatuses may include portable electronic devices such as a mobile phone, a smartphone, a portable computer, a tablet personal computer (PC), an automotive display, smart glasses, a mobile communication terminal, an electronic organizer, an electronic book, a portable multimedia player (PMP), a navigation system, an ultra mobile PC (UMPC), or the like. For example, the display device 10 may be (e.g., be applied as) a display part of a television, a laptop, a monitor, a billboard, or an Internet-of-Things (IoT) device. In other embodiments, the display device 10 may be applied to (or be included in) a smart watch, a watch phone, a head mounted display (HMD) forming virtual reality and augmented reality, and the like. The display device 10 may be a flat panel display, a curved display, a computer monitor, a medical monitor, a television, a billboard, an indoor light, an outdoor light, a signal light, a head-up display, a fully transparent display, a partially transparent display, a flexible display, a rollable display, a foldable display, a stretchable display, a laser printer, a telephone, a tablet computer, a phablet, a personal digital assistant (PDA), a wearable device, a laptop computer, a digital camera, a camcorder, a viewfinder, a micro display, a three-dimensional (3D) display, a vehicle, a video wall with multiple displays tiled together, a theater screen, a stadium screen, a phototherapy device, or a signboard.

The display device 10 according to an embodiment may include a display panel 410, a heat dissipation layer 420, a circuit board 430, a driving circuit 440, and a power supply circuit 450.

The display panel 410 may have a planar shape similar to a quadrilateral shape. For example, the display panel 410 may have a planar shape similar to a quadrilateral shape having short sides in a first direction X and long sides in a second direction Y intersecting (e.g., crossing) the first direction X. In the display panel 410, a corner where a short side in the first direction X and a long side in the second direction Y meet may be right-angled or rounded with a curvature (e.g., a predetermined or selectable curvature). The planar shape of the display panel 410 is not limited to a quadrilateral shape, and may have various shapes such as other polygonal shapes, a circular shape, an elliptical shape, or the like. The planar shape of the display device 10 may be the same or similar to (or follow) the planar shape of the display panel 410, but the embodiment of the disclosure is not limited thereto.

A display area DA may be positioned in the center of the display panel 410 and may occupy most of the area of the display panel 410. The display area DA may include a pixel group PXG, and the pixel group PXG may be a minimum part that emits white light. The pixel group PXG may include a first pixel SP1, a second pixel SP2, and a third pixel SP3. Each of the first to third pixels SP1, SP2, and SP3 may emit light of a same color or may emit light of different colors. The non-display area NDA may be adjacent to (e.g., surround) the edge of the display area DA.

The heat dissipation layer 420 may overlap the display panel 410 in a third direction Z that is a thickness direction of the display panel 410. The heat dissipation layer 420 may be disposed on a surface, for example, the rear surface of the display panel 410. The heat dissipation layer 420 may dissipate heat generated from the display panel 410. The heat dissipation layer 420 may include a metal layer having high thermal conductivity. For example, the heat dissipation layer 420 may include at least one of graphite, silver (Ag), copper (Cu), and aluminum (Al). However, the disclosure is not limited thereto.

The circuit board 430 may be positioned on the non-display area NDA of the display panel 410 by using a conductive adhesive member such as an anisotropic conductive film. For example, the circuit board 430 may be attached to the non-display area NDA of the display panel 410 by the conductive adhesive member. The circuit board 430 may be a flexible printed circuit board having a flexible material, or a flexible film. In FIG. 4, the circuit board 430 may be unfolded. However, the disclosure is not limited thereto, and the circuit board 430 may be bent. An end of the circuit board 430 may be disposed on the rear surface of the display panel 410. An end of the circuit board 430 may be opposite to another end of the circuit board 430 electrically connected to the pads of the pad area of the display panel 410 by using a conductive adhesive member.

The driving circuit 440 may receive digital video data and timing signals from the outside. The driving circuit 440 may generate a scan timing control signal, an emission timing control signal, and a data timing control signal for controlling the display panel 410 in response to the timing signals.

The power supply circuit 450 may generate panel driving voltages in response to the power voltage from the outside. For example, the power supply circuit 450 may generate and supply a first driving voltage (e.g., VSS), a second driving voltage (e.g., VDD), and a third driving voltage (e.g., VINT) to the display panel 410.

Each of the driving circuit 440 and the power supply circuit 450 may be formed as an integrated circuit (IC) and attached to a surface of the circuit board 430.

FIG. 5 is a schematic cross-sectional view of the display panel of an embodiment taken along line X1-X1′ of FIG. 4.

Referring to FIG. 5, the display panel 410 may include a semiconductor backplane SBP, a light-emitting element backplane EBP, a light-emitting element layer EML, an encapsulation layer TFE, a cover layer CVL, and a polarizing plate POL.

The semiconductor backplane SBP may include the semiconductor substrate SSUB including pixel transistors PTR, semiconductor insulating films covering the pixel transistors PTR, and contact terminals CTE electrically connected to the pixel transistors PTR, respectively.

The semiconductor substrate SSUB may be a silicon substrate, a germanium substrate, or a silicon-germanium substrate. However, the disclosure is not limited thereto. The semiconductor substrate SSUB may be a substrate doped with a first type impurity. For example, a portion of the semiconductor substrate SSUB may be doped with the first type impurity. Well regions WA may be disposed on the top surface (or upper surface) of the semiconductor substrate SSUB. The well regions WA may be regions doped with a second type impurity. The second type impurity may be different from the aforementioned first type impurity. For example, in case that the first type impurity is a p-type impurity, the second type impurity may be an n-type impurity. In other embodiments, in case that the first type impurity is an n-type impurity, the second type impurity may be a p-type impurity.

The semiconductor substrate SSUB may be replaced with a glass substrate or a polymer resin substrate such as polyimide. For example, thin film transistors may be disposed on the glass substrate or the polymer resin substrate. The glass substrate may be a rigid substrate that does not bend, and the polymer resin substrate may be a flexible substrate that may be bent or curved.

Each of the well regions WA may include a source region SA corresponding to the source electrode of the pixel transistor PTR, a drain region DRA corresponding to the drain electrode of the pixel transistor PTR, and a channel region CH disposed between the source region SA and the drain region DRA.

Each of the source region SA and the drain region DRA may be a region doped with the first type impurity. The gate electrode GE of the pixel transistor PTR may overlap the well region WA in the third direction (e.g., the Z-axis direction). The channel region CH may overlap the gate electrode GE in the third direction (e.g., the Z-axis direction). The source region SA may be disposed on a side of the gate electrode GE, and the drain region DRA may be disposed on another side of the gate electrode GE.

A first semiconductor insulating film SINS1 may be disposed on the semiconductor substrate SSUB. The first semiconductor insulating film SINS1 may include (e.g., be formed of) at least one of silicon carbonitride (SiCN), and a silicon oxide (SiOx)-based inorganic film, but the disclosure is not limited thereto.

A second semiconductor insulating film SINS2 may be disposed on the first semiconductor insulating film SINS1. The second semiconductor insulating film SINS2 may include (e.g., be formed of) a silicon oxide (SiOx)-based inorganic film, but the disclosure is not limited thereto.

The contact terminals CTE may be disposed on the second semiconductor insulating film SINS2. Each of the contact terminals CTE may be electrically connected to any one of the gate electrode GE, the source region SA, and the drain region DRA of each of the pixel transistors PTR through holes (e.g., contact holes) penetrating the first semiconductor insulating film SINS1 and the second semiconductor insulating film SINS2. The contact terminals CTE may include (e.g., be formed of) at least one of copper (Cu), aluminum (Al), tungsten (W), molybdenum (Mo), chromium (Cr), gold (Au), titanium (Ti), nickel (Ni), and neodymium (Nd). For example, the contact terminals CTE may include an alloy including any one of the above-described metals.

A third semiconductor insulating film SINS3 may be disposed on a side surface of each of the contact terminals CTE. The top surface (or upper surface) of each of the contact terminals CTE may be exposed without being covered by the third semiconductor insulating film SINS3. For example, the top surface (or upper surface) of each of the contact terminals CTE may be exposed through each of holes penetrating the third semiconductor insulating film SINS3. The third semiconductor insulating film SINS3 may include (e.g., be formed of) a silicon oxide (SiOx)-based inorganic film, but the disclosure is not limited thereto.

The light-emitting element backplane EBP may include a first metal layer ML1, a second metal layer ML2, a third metal layer ML3, a fourth metal layer ML4, a fifth metal layer ML5, a sixth metal layer ML6, a seventh metal layer ML7, an eighth metal layer ML8, reflective metal layers, a first via VA1, a second via VA2, a third via VA3, a fourth via VA4, a fifth via VA5, a sixth via VA6, a seventh via VA7, an eighth via VA8, a ninth via VA9, a tenth via VA10, and a step layer. The light-emitting element backplane EBP may include a first interlayer insulating film INS1, a second interlayer insulating film INS2, a third interlayer insulating film INS3, a fourth interlayer insulating film INS4, a fifth interlayer insulating film INS5, a sixth interlayer insulating film INS6, a seventh interlayer insulating film INS7, an eighth interlayer insulating film INS8, and a ninth interlayer insulating film INS9 disposed between the first to eighth metal layers ML1 to ML8.

The first to eighth metal layers ML1 to ML8 may electrically connect the contact terminals CTE through a hole exposing a portion of the contact terminals CTE through a hole exposing a portion of the semiconductor backplane SBP and form (e.g., implement) the circuit of the sub-pixel SP.

The first interlayer insulating film INS1 may be disposed on the semiconductor backplane SBP. Each of the first vias VA1 may penetrate the first interlayer insulating film INS1 and be electrically connected to the contact terminal CTE. A portion of the contact terminal CTE may be exposed from the semiconductor backplane SBP through a hole penetrating the first interlayer insulating film INS1. Each of the first metal layers ML1 may be disposed on the first interlayer insulating film INS and may be electrically connected to the first via VA1.

The second interlayer insulating film INS2 may be disposed on the first interlayer insulating film INS1 and the first metal layers ML1. Each of the second vias VA2 may penetrate the second interlayer insulating film INS2 and be electrically connected to the first metal layer ML1 through a hole penetrating the second interlayer insulating film INS2 exposing a portion of the first metal layer ML1. Each of the second metal layers ML2 may be disposed on the second interlayer insulating film INS2 and may be electrically connected to the second via VA2.

The third interlayer insulating film INS3 may be disposed on the second interlayer insulating film INS2 and the second metal layers ML2. Each of the third vias VA3 may penetrate the third interlayer insulating film INS3 and be electrically connected to the second metal layer ML2 through a hole penetrating the third interlayer insulating film INS3 and exposing a portion of the second metal layer ML2. Each of the third metal layers ML3 may be disposed on the third interlayer insulating film INS3, and may be electrically connected to the third via VA3.

The fourth interlayer insulating film INS4 may be disposed on the third interlayer insulating film INS3 and the third metal layers ML3. Each of the fourth vias VA4 may penetrate the fourth interlayer insulating film INS4 and be electrically connected to the third metal layer ML3 through a hole penetrating the fourth interlayer insulating film INS4 and exposing a portion of the third metal layer ML3. Each of the fourth metal layers ML4 may be disposed on the fourth interlayer insulating film INS4 and may be electrically connected to the fourth via VA4.

The fifth interlayer insulating film INS5 may be disposed on the fourth interlayer insulating film INS4 and the fourth metal layers ML4. Each of the fifth vias VA5 may penetrate the fifth interlayer insulating film INS5 and be electrically connected to the fourth metal layer ML4 through a hole penetrating the fifth interlayer insulating film INS5 and exposing a portion of the fourth metal layer ML4. Each of the fifth metal layers ML5 may be disposed on the fifth interlayer insulating film INS5 and may be electrically connected to the fifth via VA5.

The sixth interlayer insulating film INS6 may be disposed on the fifth interlayer insulating film INS5 and the fifth metal layers ML5. Each of the sixth vias VA6 may penetrate the sixth interlayer insulating film INS6 and be electrically connected to the fifth metal layer ML5 through a hole penetrating the sixth interlayer insulating film INS6 and exposing a portion of the fifth metal layer ML5. Each of the sixth metal layers ML6 may be disposed on the sixth interlayer insulating film INS6 and may be electrically connected to the sixth via VA6.

The seventh interlayer insulating film INS7 may be disposed on the sixth interlayer insulating film INS6 and the sixth metal layers ML6. Each of the seventh vias VA7 may penetrate the seventh interlayer insulating film INS7 and be electrically connected to the sixth metal layer ML6 through a hole penetrating the seventh interlayer insulating film INS7 and exposing a portion of the sixth metal layer ML6. Each of the seventh metal layers ML7 may be disposed on the seventh interlayer insulating film INS7 and may be electrically connected to the seventh via VA7.

The eighth interlayer insulating film INS8 may be disposed on the seventh interlayer insulating film INS7 and the seventh metal layers ML7. Each of the eighth vias VA8 may penetrate the eighth interlayer insulating film INS8 and be electrically connected to the seventh metal layer ML7 through a hole penetrating the eighth interlayer insulating film INS8 and exposing a portion of the seventh metal layer ML7. Each of the eighth metal layers ML8 may be disposed on the eighth interlayer insulating film INS8 and may be electrically connected to the eighth via VA8.

The first to eighth metal layers ML1 to ML8 and the first to eighth vias VA1 to VA8 may include (e.g., be formed of) a same material (or substantially the same material). The first to eighth metal layers ML1 to ML8 and the first to eighth vias VA1 to VA8 may include (e.g., be formed of) at least one of copper (Cu), aluminum (Al), tungsten (W), molybdenum (Mo), chromium (Cr), gold (Au), titanium (Ti), nickel (Ni), and neodymium (Nd). For example, the first to eighth metal layers ML1 to ML8 may include an alloy including any one of the above-described materials. The first to eighth vias VA1 to VA8 may be made of a same material (or substantially the same material). The first to eighth interlayer insulating films INS1 to INS8 may include (e.g., be formed of) a silicon oxide (SiOx)-based inorganic film, but the disclosure is not limited thereto.

The thicknesses of the first metal layer ML1, the second metal layer ML2, the third metal layer ML3, the fourth metal layer ML4, the fifth metal layer ML5, and the sixth metal layer ML6 may be greater than the thicknesses of the first via VA1, the second via VA2, the third via VA3, the fourth via VA4, the fifth via VA5, and the sixth via VA6, respectively. The thickness of each of the second metal layer ML2, the third metal layer ML3, the fourth metal layer ML4, the fifth metal layer ML5, and the sixth metal layer ML6 may be greater than the thickness of the first metal layer ML1. The thickness of the second metal layer ML2, the thickness of the third metal layer ML3, the thickness of the fourth metal layer ML4, the thickness of the fifth metal layer ML5, and the thickness of the sixth metal layer ML6 may be substantially the same.

The thickness of each of the seventh metal layer ML7 and the eighth metal layer ML8 may be greater than the thickness of each of the first metal layer ML1, the second metal layer ML2, the third metal layer ML3, the fourth metal layer ML4, the fifth metal layer ML5, and the sixth metal layer ML6. The thickness of each of the seventh metal layer ML7 and the eighth metal layer ML8 may be greater than the thickness of the seventh via VA7 and the thickness of the eighth via VA8. The thickness of each of the seventh via VA7 and the eighth via VA8 may be greater than the thickness of each of the first via VA1, the second via VA2, the third via VA3, the fourth via VA4, the fifth via VA5, and the sixth via VA6. The thickness of the seventh metal layer ML7 and the thickness of the eighth metal layer ML8 may be substantially the same.

The ninth interlayer insulating film INS9 may be disposed on the eighth interlayer insulating film INS8 and the eighth metal layers ML8. The ninth interlayer insulating film INS9 may include (e.g., be formed of) a silicon oxide (SiOx)-based inorganic film, but the embodiment of the specification is not limited thereto.

Each of the ninth vias VA9 may penetrate the ninth interlayer insulating film INS9 and be electrically connected to the eighth metal layer ML8 through a hole penetrating the ninth interlayer insulating film INS9 and exposing a portion of the eighth metal layer ML8. The ninth vias VA9 may include (e.g., be formed of) at least one of copper (Cu), aluminum (Al), tungsten (W), molybdenum (Mo), chromium (Cr), gold (Au), titanium (Ti), nickel (Ni), and neodymium (Nd). For example, the ninth vias VA9 may include an alloy including any one of the above-described materials.

The light-emitting element layer EML may be disposed on the light-emitting element backplane EBP. The light-emitting element layer EML may include a bank layer BN, a pixel defining layer PDL, and a light-emitting element ED.

The bank layer BN of an embodiment may be disposed on the ninth interlayer insulating film INS9 in an emission area EA (e.g., a portion overlapping an emission area EA) in a plan view. The bank layer BN may not overlap the non-emission area NLA in a plan view.

The bank layer BN may include a first bank layer BN1, a second bank layer BN2, and a third bank layer BN3. The first bank layer BN1, the second bank layer BN2, and the third bank layer BN3 may be sequentially stacked in the third direction (e.g., the Z-axis direction).

The first bank layer BN1 of an embodiment may be positioned on the ninth interlayer insulating film INS9. The first bank layer BN1 may cover (e.g., entirely cover) the ninth interlayer insulating film INS9.

The first bank layer BN1 may include a conductive metal having etching resistance. As an example, the first bank layer BN1 may include titanium (Ti).

The second bank layer BN2 of an embodiment may be positioned on the first bank layer BN1. The second bank layer BN2 may be electrically connected to the first bank layer BN1.

The second bank layer BN2 may include a metal with high electrical conductivity. As an example, the second bank layer BN2 may include aluminum (Al).

The third bank layer BN3 of an embodiment may be positioned on the second bank layer BN2. The third bank layer BN3 may define the emission area EA and the non-emission area NLA. The third bank layer BN3 may be electrically connected to the second bank layer BN2.

The third bank layer BN3 may include a conductive metal having etching resistance. As an example, the third bank layer BN3 may include titanium (Ti).

The edge of the third bank layer BN3 may face the non-emission area NLA, and may be tilted in a direction toward the pixel defining layer PDL. For example, a portion of the third bank layer BN3 facing the non-emission area NLA may be inclined to the third direction (e.g., the Z-axis direction). Detailed description of the third bank layer BN3 is provided below.

The pixel defining layer PDL of an embodiment may be positioned on the bank layer BN in the emission area EA (e.g., a portion overlapping the emission area EA) in a plan view. The pixel defining layer PDL may not overlap the non-emission area NLA in a plan view. The pixel defining layer PDL may include a first pixel defining layer PDL1 and a second pixel defining layer PDL2 sequentially stacked each other. The first pixel defining layer PDL1 and the second pixel defining layer PDL2 may be stacked each other in the third direction (e.g., the Z-axis direction).

The first pixel defining layer PDL1 of an embodiment may be positioned on the third bank layer BN3. The first pixel defining layer PDL1 may electrically insulate the bank layer BN from an anode electrode AE.

The first pixel defining layer PDL1 may include an inorganic insulating material. As an example, the first pixel defining layer PDL1 may include at least one of silicon oxide, silicon nitride, and silicon oxynitride. However, the disclosure is not limited thereto.

The first pixel defining layer PDL1 may include a physical property of tensile stress. For example, a portion of the first pixel defining layer PDL1 facing the non-emission area NLA may be tilted toward the third direction (e.g., the Z-axis direction). For example, a portion of the first pixel defining layer PDL1 facing the non-emission area NLA may be inclined to the third direction (e.g., the Z-axis direction). Detailed description of the first pixel defining layer PDL1 is provided below.

The second pixel defining layer PDL2 may be positioned on the first pixel defining layer PDL1 and the anode electrode AE. The second pixel defining layer PDL2 may expose an opening OP and may cover an edge of the anode electrode AE.

The second pixel defining layer PDL2 may include an inorganic insulating material. As an example, the second pixel defining layer PDL2 may include at least one of silicon oxide, silicon nitride, and silicon oxynitride. However, the disclosure is not limited thereto.

In some embodiments, the second pixel defining layer PDL2 may include a physical property of tensile stress, but is not limited thereto.

The light-emitting element ED of an embodiment may be positioned on the pixel defining layer PDL. The light-emitting element ED may include a first light-emitting element ED1 disposed in the first emission area EA1, a second light-emitting element ED2 disposed in the second emission area EA2, and a third light-emitting element ED3 disposed in the third emission area EA3. The first light-emitting element ED1, the second light-emitting element ED2, and the third light-emitting element ED3 may be spaced apart from each other.

The first light-emitting element ED1 may include a first anode electrode AE1, a first light-emitting layer EL1, a first cathode electrode CE1, and a first auxiliary electrode AX1. The second light-emitting element ED2 may include a second anode electrode AE2, a second light-emitting layer EL2, a second cathode electrode CE2, and a second auxiliary electrode AX2. The third light-emitting element ED3 may include a third anode electrode AE3, a third light-emitting layer EL3, a third cathode electrode CE3, and a third auxiliary electrode AX3.

The first light-emitting element ED1, the second light-emitting element ED2, and the third light-emitting element ED3 may emit light of different colors. For example, the first light-emitting element ED1 may emit red light, the second light-emitting element ED2 may emit green light, and the third light-emitting element ED3 may emit blue light.

The anode electrode AE of an embodiment may be positioned on the first pixel defining layer PDL1. The anode electrode AE may include the first anode electrode AE1, the second anode electrode AE2, and the third anode electrode AE3. The first anode electrode AE1 may be positioned in the first emission area EA1 (e.g., on a portion of the first pixel defining layer PDL1 overlapping the first emission area EA1 in a plan view). The second anode electrode AE2 may be positioned in the second emission area EA2 (e.g., on a portion of the first pixel defining layer PDL1 overlapping the second emission area EA2 in a plan view). The third anode electrode AE3 may be positioned in the third emission area EA3 (e.g., on a portion of the first pixel defining layer PDL1 overlapping the third emission area EA3 in a plan view).

The anode electrode AE may have a stacked structure formed by stacking a layer having a high work function and a reflective layer. For example, the layer having the high work function may include at least one of indium tin oxide (ITO), indium zinc oxide (IZO), zinc oxide (ZnO), and indium oxide (In2O3), the reflective layer may include at least one of silver (Ag), magnesium (Mg), aluminum (Al), platinum (Pt), lead (Pb), palladium (Pd), gold (Au), nickel (Ni), neodymium (Nd), iridium (Ir), chromium (Cr), and lithium (Li). For example, the reflective layer may include a mixture of the above-described materials. However, the disclosure is not limited thereto. For example, the anode electrode AE may have a multilayer structure of ITO/Mg, ITO/MgF, ITO/Ag, and ITO/Ag/ITO, but are not limited thereto.

The light-emitting layer EL of an embodiment may be disposed (or located) on the anode electrode AE. The light-emitting layer EL may be an organic light-emitting layer including (e.g., made of) an organic material, and may be formed on the anode electrode AE by the deposition process. The light-emitting layer EL may be in contact with the anode electrode AE in the opening OP (e.g., on a portion of the anode electrode AE overlapping the opening OP in a plan view).

The light-emitting layer EL may cover the pixel defining layer PDL. For example, the light-emitting layer EL may cover (e.g., entirely cover) the second pixel defining layer PDL2 and may cover a portion of the first pixel defining layer PDL1.

The light-emitting layer EL may include the first light-emitting layer EL1, the second light-emitting layer EL2, and the third light-emitting layer EL3. For example, the first light-emitting layer EL1 may emit red light, the second light-emitting layer EL2 may emit green light, and the third light-emitting layer EL3 may emit blue light, but the disclosure is not limited thereto.

The light-emitting layer EL may be formed through a photo-pattern process (or a photolithography process) during the manufacturing process. For example, the light-emitting layer EL may be formed without a separate fine metal mask during the manufacturing process. Accordingly, the display panel 410 may include the first light-emitting layer EL1, the second light-emitting layer EL2, and the third light-emitting layer EL3 spaced apart from each other at a narrow gap. Detailed description of the manufacturing process is provided below.

The cathode electrode CE of an embodiment may be disposed (or located) on the light-emitting layer EL. The cathode electrode CE may cover (e.g., entirely cover) the light-emitting layer EL.

The cathode electrode CE may include a transparent conductive material, and the light generated in the light-emitting layer EL may be emitted through the cathode electrode CE. For example, the cathode electrode CE may include a layer having a low work function. For example, the cathode electrode CE may include at least one of Li, Ca, LiF/Ca, LiF/Al, Al, Mg, Ag, Pt, Pd, Ni, Au Nd, Ir, Cr, BaF, and Ba. The cathode electrode CE may include a compound or mixture thereof (e.g., a mixture of Ag and Mg). The cathode electrode CE may further include a transparent metal oxide layer disposed on the layer having a low work function.

The cathode electrode CE may include the first cathode electrode CE1, the second cathode electrode CE2, and the third cathode electrode CE3. The first cathode electrode CE1 may be positioned in the first emission area EA1 (e.g., on a portion of the light-emitting layer EL overlapping the first emission area EA1 in a plan view). The second cathode electrode CE2 may be positioned in the second emission area EA2 (e.g., on a portion of the light-emitting layer EL overlapping the second emission area EA2 in a plan view). The third cathode electrode CE3 may be positioned in the third emission area EA3 (e.g., on a portion of the light-emitting layer EL overlapping the third emission area EA3 in a plan view).

The first cathode electrode CE1, the second cathode electrode CE2, and the third cathode electrode CE3 may be spaced apart from each other. Each of the first cathode electrode CE1, the second cathode electrode CE2, and the third cathode electrode CE3 may not be directly connected to each other (or may not be in direct contact with each other), but may be electrically connected to each other through the auxiliary electrode AX and the bank layer BN.

The auxiliary electrode AX of an embodiment may be disposed (or located) on the cathode electrode CE. The auxiliary electrode AX may cover (e.g., entirely cover) the cathode electrode CE.

The auxiliary electrode AX may include at least one of a transparent conductive material (TCO) and a conductive metal.

The auxiliary electrode AX may include the first auxiliary electrode AX1, the second auxiliary electrode AX2, and the third auxiliary electrode AX3. The first auxiliary electrode AX1 may be positioned in the first emission area EA1 (e.g., on a portion of the cathode electrode CE overlapping the first emission area EA1 in a plan view). The second auxiliary electrode AX2 may be positioned in the second emission area EA2 (e.g., on a portion of the cathode electrode CE overlapping the second emission area EA2 in a plan view). The third auxiliary electrode AX3 may be positioned in the third emission area EA3 (e.g., on a portion of the cathode electrode CE overlapping the third emission area EA3 in a plan view).

The first auxiliary electrode AX1, the second auxiliary electrode AX2, and the third auxiliary electrode AX3 may be spaced apart from each other. The first auxiliary electrode AX1, the second auxiliary electrode AX2, and the third auxiliary electrode AX3 may not be directly connected to each other (or may not be in direct contact with each other), but may be electrically connected to each other through the bank layer BN.

The encapsulation layer TFE of an embodiment may be disposed on the light-emitting element layer EML. The encapsulation layer TFE may include at least one inorganic film and an organic film and prevent oxygen or moisture from permeating into the light-emitting element layer EML. For example, the encapsulation layer TFE may include two or more inorganic films (or an inorganic film) and an organic film.

The encapsulation layer TFE may include a first encapsulation layer TFE1, a second encapsulation layer TFE2, and a third encapsulation layer TFE3.

The first encapsulation layer TFE1 of an embodiment may be positioned on the light-emitting element ED. The first encapsulation layer TFE1 may cover the bank layer BN and the light-emitting element ED. The first encapsulation layer TFE1 may cover the lower structure (e.g., the light-emitting element ED) along a profile (e.g., a profile of the lower structure) with a uniform thickness. Accordingly, the first encapsulation layer TFE1 may include a stepped portion.

The first encapsulation layer TFE1 may include an inorganic insulating material. As an example, the first encapsulation layer TFE1 may include at least one of silicon oxide, silicon nitride, and silicon oxynitride. However, the disclosure is not limited thereto.

The first encapsulation layer TFE1 may include a first inorganic layer TFE11, a second inorganic layer TFE12, and a third inorganic layer TFE13. The first inorganic layer TFE11 may be positioned in the first emission area EA1 (e.g., on a portion of the light-emitting element ED overlapping the first emission area EA1 in a plan view). The second inorganic layer TFE12 may be positioned in the second emission area EA2 (e.g., on a portion of the light-emitting element ED overlapping the second emission area EA2 in a plan view). The third inorganic layer TFE13 may be positioned in the third emission area EA3 (e.g., on a portion of the light-emitting element ED overlapping the third emission area EA3 in a plan view).

The first inorganic layer TFE11, the second inorganic layer TFE12, and the third inorganic layer TFE13 may be spaced apart from each other. In the drawing, the first inorganic layer TFE11, the second inorganic layer TFE12, and the third inorganic layer TFE13 may be formed in a same layer, but the first inorganic layer TFE11, the second inorganic layer TFE12, and the third inorganic layer TFE13 may be formed in different processes. For example, the first inorganic layer TFE1l may be formed after the first light-emitting element ED1 is formed, the second inorganic layer TFE12 may be formed after the second light-emitting element ED2 is formed, and the third inorganic layer TFE13 may be formed after the third light-emitting element ED3 is formed. Detailed description of the manufacturing process is provided below.

The second encapsulation layer TFE2 of an embodiment may be positioned on the first encapsulation layer TFE1. The second encapsulation layer TFE2 may planarize the stepped portion formed by the first encapsulation layer TFE1 in the emission area EA and the non-emission area NLA (e.g., on a portion of the first encapsulation layer TFE1 overlapping the emission area EA and the non-emission area NLA in a plan view).

The second encapsulation layer TFE2 may include a polymer-based material. As an example, the second encapsulation layer TFE2 may include at least one of acrylic resin, silicone resin, silicone acrylic resin, and epoxy resin. However, the disclosure is not limited thereto, and the second encapsulation layer TFE2 may include various polymer resins. The second encapsulation layer TFE2 may be formed by curing a monomer or applying a polymer.

The third encapsulation layer TFE3 of an embodiment may be positioned on the second encapsulation layer TFE2 and cover (e.g., completely cover) the second encapsulation layer TFE2. The third encapsulation layer TFE3 and the first encapsulation layer TFE1 may include a same material. In other embodiments, the third encapsulation layer TFE3 may be omitted.

The cover layer CVL may be disposed on the encapsulation layer TFE. The cover layer CVL may be a glass substrate or a polymer resin. In case that the cover layer CVL is a glass substrate, the cover layer CVL may be an encapsulation substrate. For example, in case that the cover layer CVL is a polymer resin such as resin, an adhesive layer may be disposed (e.g., added) between the cover layer CVL and the encapsulation layer TFE.

The polarizing plate POL may be disposed on the cover layer CVL. The polarizing plate POL may be a structure for reducing or preventing reflection of external light, and improve visibility of the display device 10 (e.g., refer to FIG. 4). The polarizing plate POL may include a linear polarizing plate and a phase retardation film. For example, the phase retardation film may be a 24 plate (or quarter-wave plate), but the disclosure is not limited thereto.

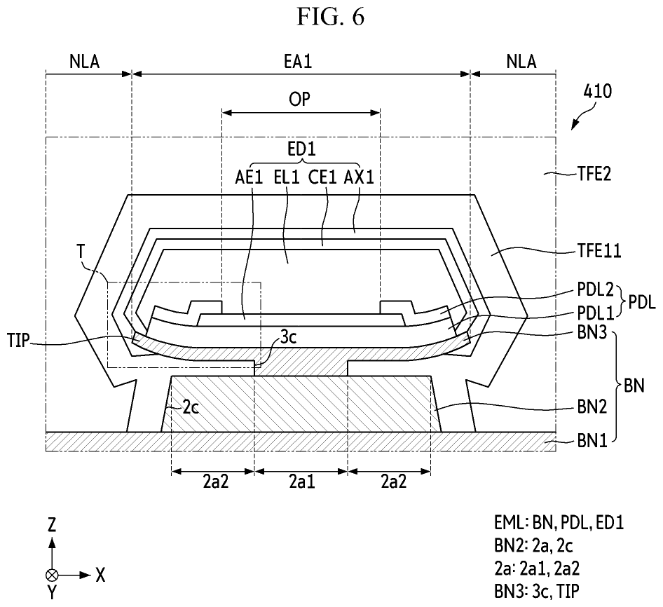

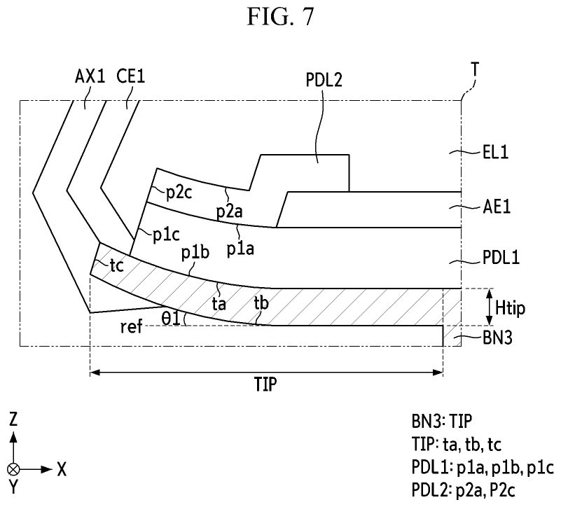

FIG. 6 is a schematic enlarged cross-sectional view of the light-emitting element layer overlapping the first emission area in FIG. 5 in a plan view. FIG. 7 is a schematic enlarged cross-sectional view of area T in FIG. 6.

Referring to FIGS. 6 and 7, the light-emitting element layer EML may be disposed in the first emission area EA1 (e.g., on a portion of the ninth interlayer insulating film INS9 of FIG. 6 overlapping the first emission area EA1 in a plan view), and may include the bank layer BN, the pixel defining layer PDL, and the first light-emitting element ED1.

The second bank layer BN2 of an embodiment may be positioned in contact with and on the first bank layer BN1. The second bank layer BN2 may include a top surface (or upper surface) 2a and a side surface 2c. The top surface (or upper surface) 2a may face the third bank layer BN3, and the side surface 2c may face the non-emission area NLA.

The top surface (or upper surface) 2a of the second bank layer BN2 may be divided into a first portion 2al and a second portion 2a2 depending on the contact portion. The first portion 2al may be a portion in contact with the third bank layer BN3, and the second portion 2a2 may be a portion in contact with the first inorganic layer TFE11. Second portions 2a2 may be formed, and the second portions 2a2 may be spaced apart from each other with the first portion 2al disposed (e.g., interposed) between adjacent ones of the second portions 2a2.

The third bank layer BN3 of an embodiment may be positioned in contact with and on the second bank layer BN2.

The third bank layer BN3 may include a first side surface 3c positioned in the opening OP (e.g., on a portion of the second bank layer BN2 overlapping the opening OP in a plan view). The third bank layer BN3 may include a tip TIP that protrudes further in a direction toward the non-emission area NLA than the first side surface 3c. The tip TIP of the third bank layer BN3 may protrude in the first direction (e.g., the X-axis direction) further than the first side surface 3c. Accordingly, an undercut may be formed between the tip TIP of the third bank layer BN3 and the first side surface 3c of the third bank layer BN3.

In some embodiments, the tip TIP of the third bank layer BN3 may include a first surface ta, a second surface tb, and a second side surface tc. The first surface ta of the tip TIP may be in contact with the first pixel defining layer PDL1. The second surface tb may be opposite to the first surface ta. The second side surface the may be a surface connecting the first surface ta and the second surface tb. For example, the second side surface tc may extend from the first surface ta toward the second surface tb.

The first surface ta and the second surface tb of the tip TIP may be curved surfaces tilted in a direction toward the first pixel defining layer PDL1. For example, the first surface ta and the second surface tb of the tip TIP may be curved surfaces inclined toward the third direction (e.g., the Z-axis direction) by a first inclination angle θ1 with respect to a horizontal reference line ref in the first direction (e.g., the X-axis direction). For example, the first inclination angle θ1 may have a value greater than or equal to about 0.1 degrees.

The first pixel defining layer PDL1 of an embodiment may be positioned on the third bank layer BN3. The first pixel defining layer PDL1 may be in contact with the first surface ta of the third bank layer BN3.

In some embodiments, the first pixel defining layer PDL1 may include a first surface p1a, a second surface p1b, and a first side surface plc. The first surface p1a of the first pixel defining layer PDL1 may be in contact with the second pixel defining layer PDL2. The second surface p1b may be opposite to the first surface p1a. The first side surface plc may be a surface connecting the first surface p1a and the second surface p1b. For example, the first side surface plc may extend from the first surface p1a to the second surface p1b.

The first surface p1a and the second surface p1b of the first pixel defining layer PDL1 may be curved surfaces tilted in a direction toward the second pixel defining layer PDL2 on the tip TIP of the third bank layer BN3 (e.g., on a portion overlapping the tip TIP of the third bank layer BN3 in a plan view). For example, the first surface p1a and the second surface p1b of the first pixel defining layer PDL1 may be curved surfaces inclined toward the third direction (e.g., the Z-axis direction) with respect to the horizontal reference line ref in the first direction (e.g., the X-axis direction).

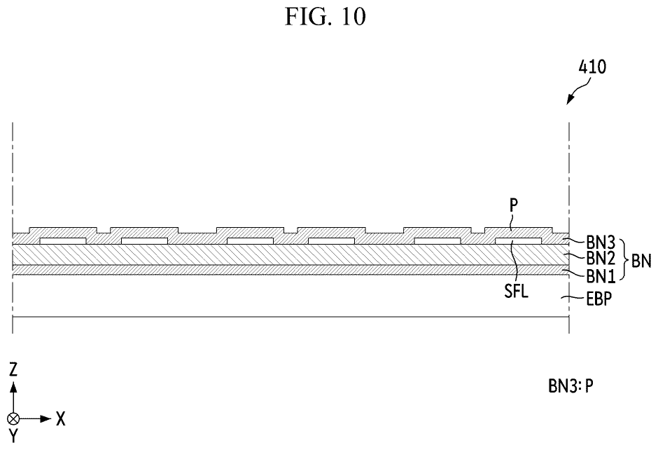

During the manufacturing process of the display panel 410, the first surface ta of the tip TIP included in the third bank layer BN3 may be in contact with the first pixel defining layer PDL1, and the second surface tb of the tip TIP may be in contact with a sacrificial layer SFL (e.g., refer to FIG. 10). In other embodiments, the first surface ta and second surface tb of the tip TIP and the first surface p1a and second surface p1b of the first pixel defining layer PDL1 may not be inclined but may be flat.

The sacrificial layer SFL (e.g., refer to FIG. 10) may be removed through a subsequent etching process. For example, the first surface ta and the second surface tb of the tip TIP of the third bank layer BN3, and the first surface p1a and the second surface p1b of the first pixel defining layer PDL1 may be inclined to the third direction (e.g., the Z-axis direction). The inclination may be caused by the material properties of the third bank layer BN3 and the first pixel defining layer PDL1.

For example, the third bank layer BN3 may have a curved surface formed on a portion of the tip TIP due to metal tile phenomena occurring at a thickness in a range (e.g., a certain or selectable range). A height Htip of the tip TIP of the third bank layer BN3 may be less than or equal to about 2000 angstroms. The height Htip may be in a range in which metal tile phenomena occur.

Portions of the third bank layer BN3 and the first pixel defining layer PDL1 may have curved surfaces formed due to the tensile stress of the first pixel defining layer PDL1. For example, the first pixel defining layer PDL1 may assist the tip TIP of the third bank layer BN3 to be more inclined. For example, the first pixel defining layer PDL1 may increase the inclination of the tip TIP of the third bank layer BN3. Detailed description of the manufacturing process is provided below.

The second pixel defining layer PDL2 of an embodiment may surround the opening OP and expose the first anode electrode AE1. The second pixel defining layer PDL2 may be in contact with the first pixel defining layer PDL1 and the first anode electrode AE1.

The second pixel defining layer PDL2 may include a first surface p2a and a first side surface p2c. The first surface p2a of the second pixel defining layer PDL2 may be in contact with the first light-emitting layer EL1, and the first side surface p2c may face the non-emission area NLA.

The first side surface p2c of the second pixel defining layer PDL2 and the first side surface plc of the first pixel defining layer PDL1 may be positioned on a same virtual line. During the manufacturing process of the display panel 410, a portion of the first pixel defining layer PDL1 and a portion of the second pixel defining layer PDL2 may be removed in a same process. Accordingly, the first side surface p2c of the second pixel defining layer PDL2 and the first side surface p1e of the first pixel defining layer PDL1 may be aligned. Detailed description of the manufacturing process is provided below.

The first surface p2a of the second pixel defining layer PDL2 may have a curved surface similar to the first surface p1a of the first pixel defining layer PDL1, but the disclosure is not limited thereto. In other embodiments, the first surface p2a of the second pixel defining layer PDL2 may be flat.

The first light-emitting layer EL1 of an embodiment may be in contact with the pixel defining layer PDL and the first anode electrode AE1. The first light-emitting layer EL1 may cover (e.g., completely cover) the second pixel defining layer PDL2 and may cover a portion of the first pixel defining layer PDL1. For example, the first light-emitting layer EL1 may be in contact with the first side surface plc of the first pixel defining layer PDL1 and the first side surface p2c of the second pixel defining layer PDL2.

The first cathode electrode CE1 of an embodiment may be in contact with and cover (e.g., be entirely in contact with and entirely cover) the first light-emitting layer EL1. The first cathode electrode CE1 may cover (e.g., completely cover) the first side surface plc of the first pixel defining layer PDL1 and the first side surface p2c of the second pixel defining layer PDL2, and may be in contact with the first side surface p1e of the first pixel defining layer PDL1.

The first auxiliary electrode AX1 of an embodiment may be in contact with and cover (e.g., be entirely in contact with and entirely cover) the first cathode electrode CE1. The first cathode electrode CE1 may be electrically connected to the bank layer BN through the first auxiliary electrode AX1.

The first auxiliary electrode AX1 may cover an inclined portion of the tip TIP of the third bank layer BN3. For example, the first auxiliary electrode AX1 may be in contact with the second surface tb and the second side surface the of the third bank layer BN3.

The display panel 410 of an embodiment may increase the contact area between the first auxiliary electrode AX1 and the third bank layer BN3 by including a shape in which a portion of the tip TIP of the third bank layer BN3 facing the non-emission area NLA is inclined toward the pixel defining layer PDL. For example, the portion of the tip TIP of the third bank layer BN3 facing the non-emission area NLA may be inclined toward the pixel defining layer PDL, and the contact area between the first auxiliary electrode AX1 and the third bank layer BN3 may be increased. Accordingly, the display panel 410 may solve a contact defect between the first cathode electrode CE1 and the third bank layer BN3 and lower the electrical resistance of the display panel 410. For example, the contact defect between the first cathode electrode CE1 and the third bank layer BN3 may be prevented, and the electrical resistance of the display panel 410 may be decreased.

The first inorganic layer TFE11 of an embodiment may cover (e.g., entirely cover) the bank layer BN and the first light-emitting element ED1. The first inorganic layer TFE11 may be in contact with the bank layer BN and the first auxiliary electrode AX1.

The display panel 410 of an embodiment may delay (or prevent) moisture permeation caused from the outside of the display device 10 by increasing the contact area between the first inorganic layer TFE11 and the bank layer BN.

In some embodiments, the undercut formed between the tip TIP of the third bank layer BN3 and the first side surface 3c of the third bank layer BN3 may be filled (e.g., completely filled) by the first inorganic layer TFE11.

The first inorganic layer TFE11 may include a stepped portion according to the profile of the lower structure (e.g., the first light-emitting element ED1, the pixel defining layer PDL, the bank layer BN, or the like), and the stepped portion formed by the first inorganic layer TFE11 may be planarized by the second encapsulation layer TFE2.

For simplicity of description, the light-emitting element layer EML overlapping the first emission area EA1 in a plan view and the light-emitting element layers EML overlapping the second emission area EA2 and the third emission area EA3 in a plan view may have a same structure and feature.

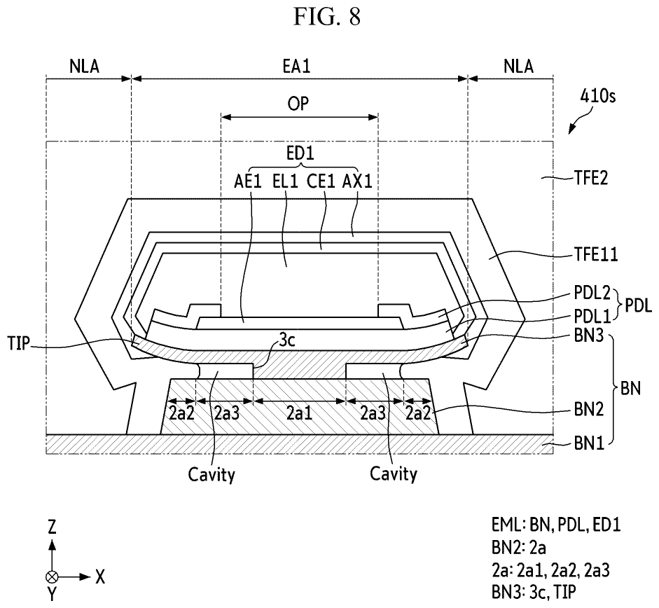

FIG. 8 is a schematic enlarged cross-sectional view of a light-emitting element layer according to an embodiment overlapping the first emission area in FIG. 5 in a plan view.

Referring to FIG. 8, a display panel 410s of an embodiment may be different from the display panel 410 (e.g., refer to FIG. 6) at least in that a cavity is formed between the second bank layer BN2 and the third bank layer BN3 in the display panel 410s. Hereinafter, detailed description of the same or similar constituent elements is omitted.

The second bank layer BN2 of an embodiment may include the top surface (or upper surface) 2a. The top surface (or upper surface) 2a may face the third bank layer BN3. The top surface (or upper surface) 2a of the second bank layer BN2 may be divided into the first portion 2a1, the second portion 2a2, and a third portion 2a3 depending on the contact portion.

The first portion 2al may be a portion in contact with the third bank layer BN3, the second portion 2a2 may be a portion in contact with the first inorganic layer TFE11, and the third portion 2a3 may be a portion in contact with the cavity. In the first direction (e.g., the X-axis direction), the third portion 2a3 may be positioned between the first portion 2al and the second portion 2a2.

An undercut may be formed between the tip TIP of the third bank layer BN3 and the first side surface 3c of an embodiment. During the manufacturing process of the display panel 410s, the undercut formed between the tip TIP of the third bank layer BN3 and the first side surface 3c of the third bank layer BN3 may be formed to be narrow and deep. Accordingly, depending on the step coverage characteristics of the first inorganic layer TFE11, a portion of the undercut may not be filled by the first inorganic layer TFE11. The cavity may be formed in a portion of the undercut that is not filled by the first inorganic layer TFE11. For example, the cavity may be an empty space.

The cavity may be formed in the first emission area EA1 (e.g., on a portion of the second bank layer BN2 overlapping the first emission area EA1 in a plan view) and may not overlap the non-emission area NLA. The cavity may be formed between the second bank layer BN2 and the third bank layer BN3 in the third direction (e.g., the Z-axis direction), and may overlap the pixel defining layer PDL and the first light-emitting element ED1 in the third direction (e.g., the Z-axis direction).

The display panel 410s of an embodiment may include a shape in which a portion of the tip TIP of the third bank layer BN3 is inclined toward the pixel defining layer PDL in a portion that does not overlap the cavity in a plan view. Thus, the contact area between the first auxiliary electrode AX1 and the third bank layer BN3 may be increased. Accordingly, the display panel 410s may solve a contact defect between the first cathode electrode CE1 and the third bank layer BN3 and lower the electrical resistance of the display panel 410s. For example, the contact defect between the first cathode electrode CE1 and the third bank layer BN3 may be prevented, and the electrical resistance of the display panel 410s may be decreased. Detailed description of the same or similar constituent elements is omitted.

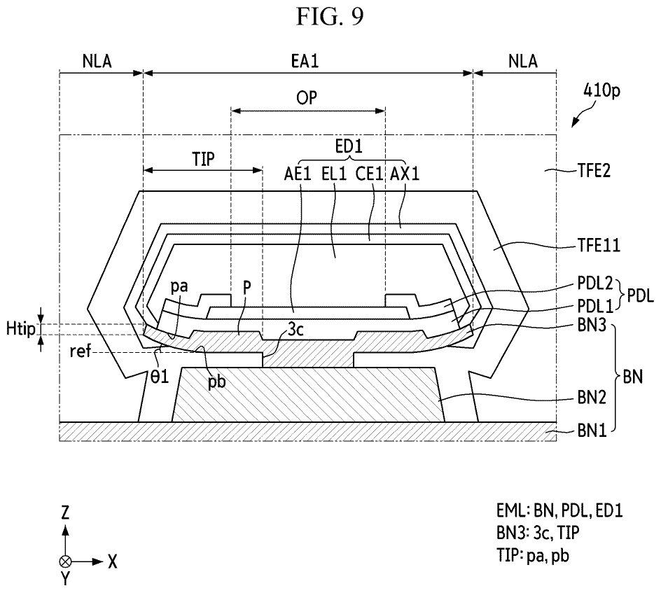

FIG. 9 is a schematic enlarged cross-sectional view of a light-emitting element layer according to an embodiment overlapping the first emission area in FIG. 5 in a plan view.

Referring to FIG. 9, the display panel 410p of an embodiment is different from the display panel 410 (e.g., refer to FIG. 6) at least in the shape of the third bank layer BN3. Hereinafter, detailed description of the same constituent elements is omitted.

The display panel 410p of an embodiment may include a protrusion P in which a portion of the third bank layer BN3 protrudes in a direction (e.g., a Z-axis direction) toward the pixel defining layer PDL.

During the manufacturing process of the display panel 410p, the third bank layer BN3 may cover (e.g., entirely cover) the sacrificial layer SFL (e.g., refer to FIG. 10). Accordingly, the third bank layer BN3 may have a stepped portion according to the profile formed by the sacrificial layer SFL. A portion of the third bank layer BN3 positioned on the sacrificial layer SFL (e.g., on a portion on the second bank layer BN2 overlapping the sacrificial layer SFL in a plan view), and may have the protrusion P protruding further toward the third direction (e.g., the Z-axis direction) than another portion of the third bank layer BN3 positioned out of the sacrificial layer SFL (e.g., on the portion of the second bank layer BN2 not overlapping the sacrificial layer SFL in a plan view).

The protrusion P of the third bank layer BN3 may be formed in the first emission area EA1 (e.g., on a portion of the second bank layer BN2 overlapping the first emission area EA1 in a plan view) and may not overlap the non-emission area NLA in a plan view.

The tip TIP of the third bank layer BN3 included in the display panel 410p may include a first surface pa and a second surface pb. The first surface pa of the tip TIP may not overlap the protrusion P in a plan view and may face the first pixel defining layer PDL1. The second surface pb of the tip TIP may face the second bank layer BN2. The second surface pb may oppose the first surface pa in a portion that does not overlap the protrusion P in a plan view.

The second surface pb and the first surface pa of the tip TIP of the third bank layer BN3 may be curved surfaces tilted in a direction (e.g., a Z-axis direction) toward the first pixel defining layer PDL1. For example, the second surface pb and the first surface pa of the tip TIP of the third bank layer BN3 may be curved surfaces inclined toward the third direction (e.g., the Z-axis direction) by the first inclination angle θ1 with respect to the horizontal reference line ref in the first direction (e.g., the X-axis direction). For example, the first inclination angle θ1 may have a value greater than or equal to about 0.1 degrees.

In some embodiments, the height Htip of the tip TIP of the third bank layer BN3 in a portion that does not overlap the protrusion P in a plan view may be less than or equal to about 2,000 angstroms, but is not limited thereto.

The first pixel defining layer PDL1 included in the display panel 410p may cover (e.g., entirely cover) the protrusion P of the third bank layer BN3 and may be in contact with the protrusion P. The first light-emitting element ED1 may overlap the protrusion P of the third bank layer BN3 in the third direction (e.g., the Z-axis direction). The first inorganic layer TFE11 may cover (e.g., entirely cover) the protrusion P of the third bank layer BN3. Detailed description of the same or similar constituent elements is omitted.

The display panel 410p of an embodiment may include a shape in which a portion of the tip TIP of the third bank layer BN3 is inclined toward the pixel defining layer PDL in a portion that does not overlap the protrusion P of the third bank layer BN3 in a plan view. For example, the display panel 410p may increase the contact area between the first auxiliary electrode AX1 and the third bank layer BN3. Accordingly, the display panel 410p may solve a contact defect between the first cathode electrode CE1 and the third bank layer BN3 and lower the electrical resistance of the display panel 410p. For example, the contact defect between the first cathode electrode CE1 and the third bank layer BN3 may be prevented, and the electrical resistance of the display panel 410p may be decreased.

The display panel 410p of an embodiment may be readily (or easily) manufactured by omitting the removing of the protrusion P of the third bank layer BN3. Detailed description of the same or similar constituent elements is omitted.

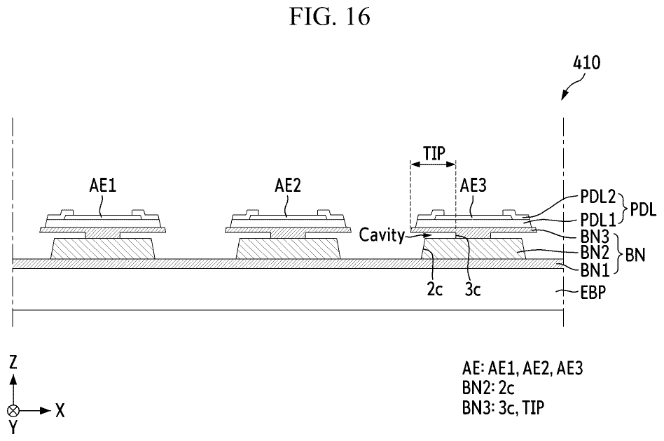

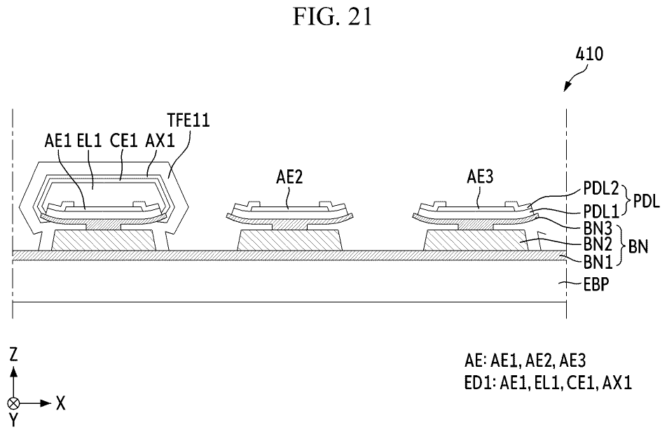

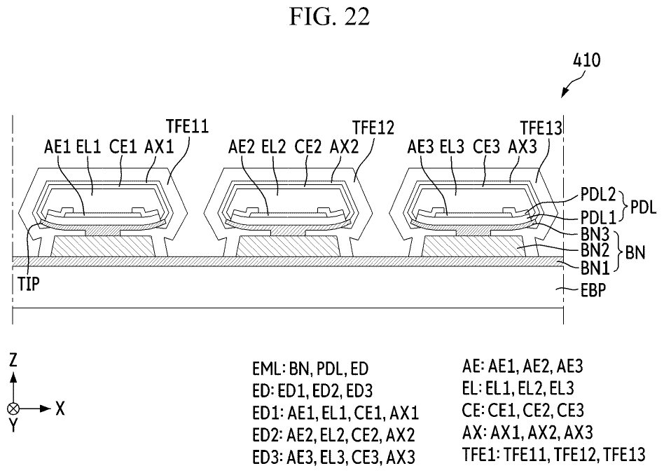

FIGS. 10 to 22 are schematic cross-sectional views sequentially illustrating a manufacturing process of a light-emitting element layer of a display panel according to an embodiment. Hereinafter, detailed description of the manufacturing process of the light-emitting element layer is provided with respect to an order of layers to be formed.

Referring to FIG. 10, the bank layer BN and the sacrificial layer SFL may be formed on the light-emitting element backplane EBP. The bank layer BN may include the first bank layer BN1, the second bank layer BN2, and the third bank layer BN3. The structure of the light-emitting element backplane EBP may be the same as described above with reference to FIG. 5. Detailed description of the same or similar constituent elements is omitted.

The first bank layer BN1 may cover (e.g., entirely cover) the light-emitting element backplane EBP. The second bank layer BN2 may cover (e.g., entirely cover) the first bank layer BN1.

The sacrificial layer SFL may be formed on the second bank layer BN2. For example, multiple sacrificial layers SFL may be formed, and the sacrificial layers SFL may be spaced apart from each other on the second bank layer BN2.

The sacrificial layer SFL may include an oxide semiconductor. As an example, the sacrificial layer SFL may include at least one of indium-gallium-zinc oxide (IGZO), zinc-tin oxide (ZTO), and indium-zinc oxide (IZO). However, the disclosure is not limited thereto.

The third bank layer BN3 may be positioned on the sacrificial layers SFL. The third bank layer BN3 may cover (e.g., entirely cover) the surfaces of the sacrificial layers SFL. The third bank layer BN3 may cover the stepped portions formed by the sacrificial layers SFL with a uniform thickness. Accordingly, the third bank layer BN3 may include the protrusions P at portions overlapping the sacrificial layers SFL in a plan view.

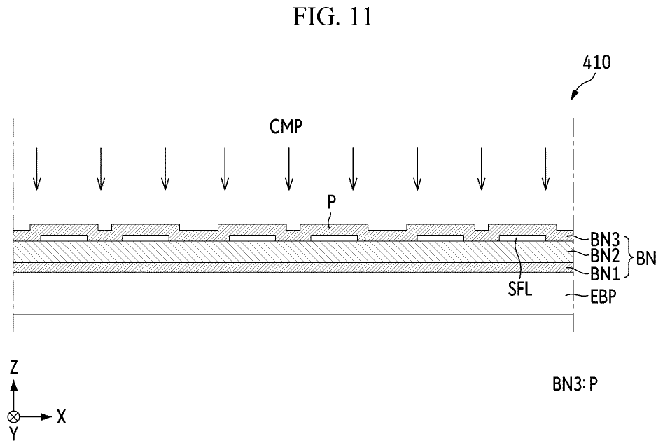

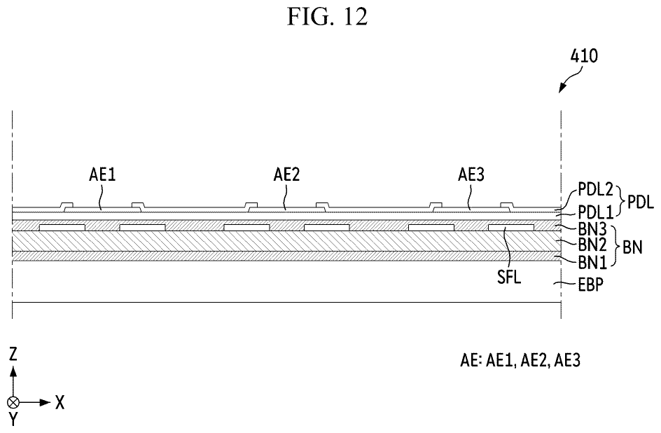

Referring to FIGS. 11 and 12, the protrusion P of the third bank layer BN3 may be removed through a chemical mechanical polishing (CMP) process. In the process (e.g., the CMP process), the third bank layer BN3 may include a flat surface without any stepped portions.

The pixel defining layer PDL and the anode electrode AE may be formed on the bank layer BN. The pixel defining layer PDL may include the first pixel defining layer PDL1 and the second pixel defining layer PDL2.

The first pixel defining layer PDL1 may be formed on (e.g., be entirely formed on) the third bank layer BN3. For example, the first pixel defining layer PDL1 may include an inorganic insulating material having tensile stress. For example, the tensile stress may be applied to the first pixel defining layer PDL1.

The anode electrode AE may be positioned on the first pixel defining layer PDL1. The anode electrode AE may include the first anode electrode AE1, the second anode electrode AE2, and the third anode electrode AE3. The first anode electrode AE1, the second anode electrode AE2, and the third anode electrode AE3 may be spaced apart from each other.

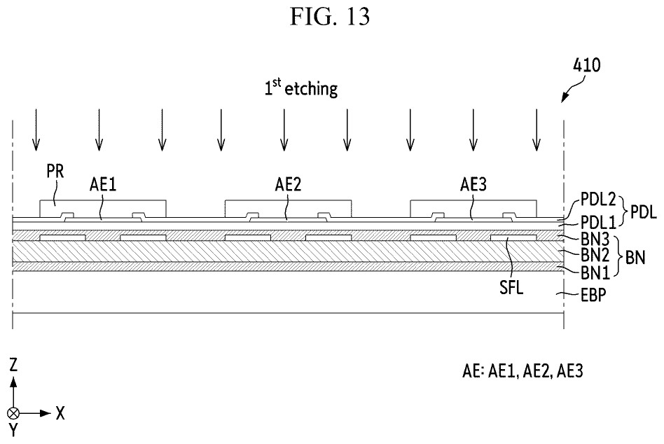

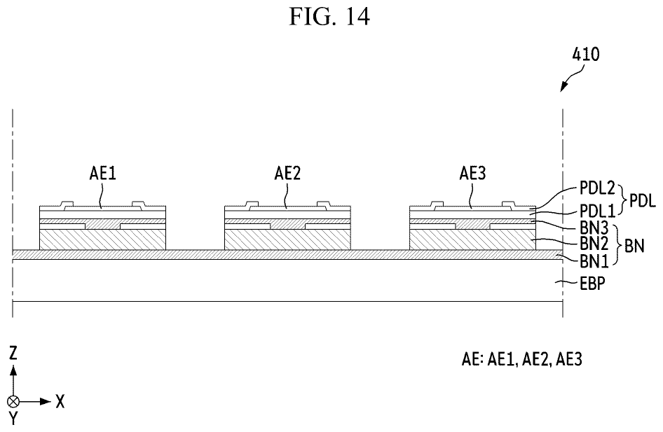

The second pixel defining layer PDL2 may expose a portion of the anode electrode AE and may surround an edge of the anode electrode AE. The second pixel defining layer PDL2 and the first pixel defining layer PDL1 may include a same material, but is not limited thereto. Referring to FIGS. 13 and 14, photoresists PR may be formed on the anode electrode AE and the second pixel defining layer PDL2. The photoresists PR may be spaced apart from each other, and the photoresists PR may cover (e.g., completely cover) each of the first anode electrode AE1, the second anode electrode AE2, and the third anode electrode AE3.

A first etching process (or 1^{st} etching) may be performed using the photoresists PR as a mask (e.g., an etching mask). For example, the first etching process (or 1^{st} etching) may be performed as a dry etching process.

In the process (e.g., the dry etching process), portions of the pixel defining layer PDL, the second bank layer BN2, and the third bank layer BN3 may be isotropically removed. For example, in the process (e.g., the dry etching process), the pixel defining layer PDL, the second bank layer BN2, and the third bank layer BN3 may have side surfaces positioned on a same virtual line.

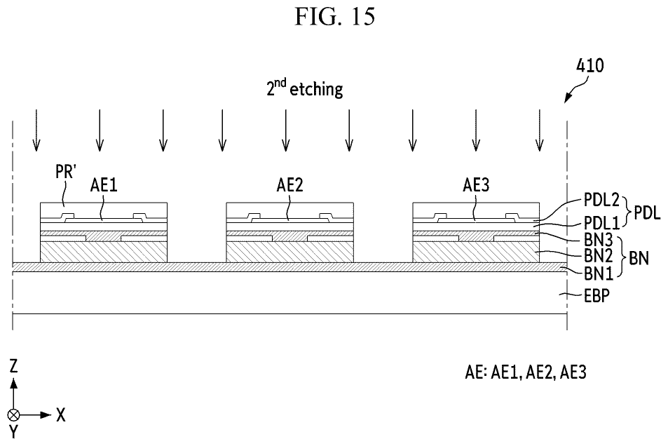

Referring to FIGS. 15 to 18, photoresists PR′ may be formed at same positions used in the first etching process (or 1^{st} etching), and a second etching process (or 2^{nd} etching) may be performed. For example, the second etching process (or 2^{nd} etching) may be performed as a wet etching process.

In the process (e.g., the second etching process), the second bank layer BN2 and the third bank layer BN3 including different materials may be different in etch selectivity. For example, since the second bank layer BN2 includes a material having a higher etching rate than the third bank layer BN3, the side surface 2c of the second bank layer BN2 may be recessed further in the first direction (e.g., the X-axis direction) than the third bank layer BN3.

In the process (e.g., the second etching process), the sacrificial layer SFL positioned between the second bank layer BN2 and the third bank layer BN3 may be removed. The removing of the sacrificial layer SFL may perform the removal simultaneously with the etching of the second bank layer BN2 and the third bank layer BN3. In other embodiments, the removing the sacrificial layer SFL may be continued after the second bank layer BN2 and the third bank layer BN3 have been etched.

In the process (e.g., the second etching process), the cavity may be formed between the second bank layer BN2 and the third bank layer BN3 in the third direction (e.g., the Z-axis direction). The cavity may be a portion from which the sacrificial layer SFL has been removed. In the process (e.g., the second etching process), the third bank layer BN3 may include the tip TIP in the cavity (e.g., on a portion of the second bank layer BN2 overlapping the cavity in a plan view). The tip TIP of the third bank layer BN3 may be a portion that protrudes further in the first direction (e.g., the X-axis direction) than the first side surface 3c of the third bank layer BN3.

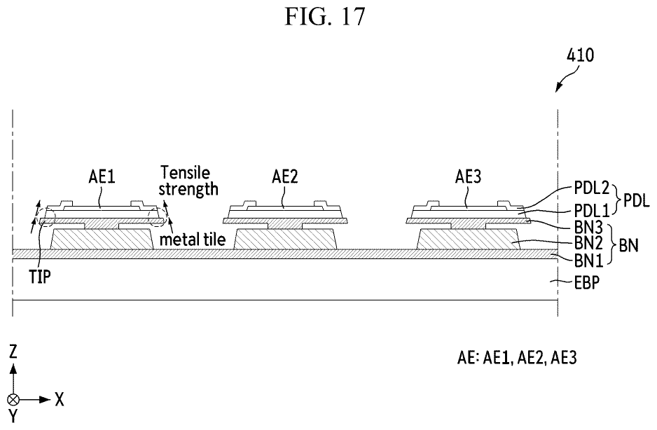

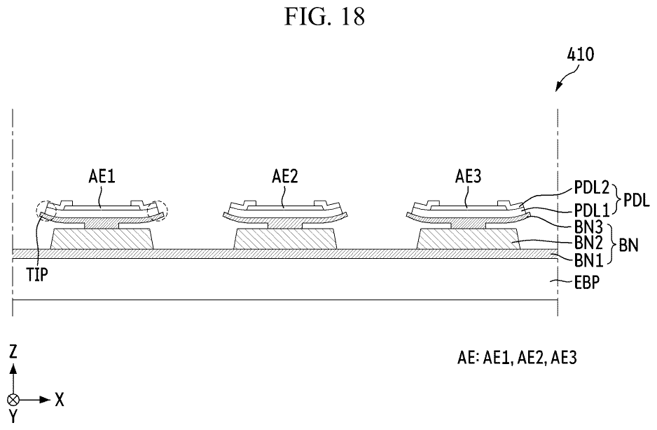

As illustrated in FIGS. 17 and 18, in the process (e.g., the second etching process), the edges of the tips (e.g., both tips) TIP of the third bank layer BN3 may be inclined to the third direction (e.g., the Z-axis direction). For example, the tip TIP of the third bank layer BN3 may be partially inclined to the third direction (e.g., the Z-axis direction) due to metal tile phenomena caused by metal physical properties of the tip TIP. The tip TIP of the third bank layer BN3 may be inclined to the third direction (e.g., the Z-axis direction) due to the tensile strength of the first pixel defining layer PDL1. For example, in the process (e.g., the second etching process), the first pixel defining layer PDL1 may assist the tip TIP of the third bank layer BN3 to be inclined more. For example, the first pixel defining layer PDL1 may increase the inclination of the tip TIP of the third bank layer BN3.

In other embodiments, a surface of the second pixel defining layer PDL2 may have a curved surface in the third direction (e.g., the Z-axis direction). In other embodiments, a surface of the second pixel defining layer PDL2 may not have a curved surface.

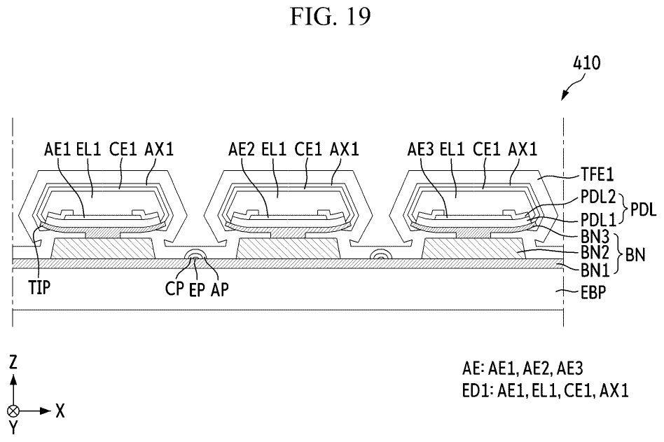

Referring to FIG. 19, the first light-emitting element ED1 may be formed by depositing the first light-emitting layer EL1, the first cathode electrode CE1, and the first auxiliary electrode AX1 on the first anode electrode AE1.

In the process (e.g., the forming of the first light-emitting element ED1), the first light-emitting layer EL1 may be formed through a thermal evaporation process. The forming of the first light-emitting layer EL1 may be performed without using a separate fine metal mask. Accordingly, the material forming the first light-emitting layer EL1 may be formed on the first anode electrode AE1, the second anode electrode AE2, the third anode electrode AE3, and the first bank layer BN1.

In the process (e.g., the forming of the first light-emitting element ED1), the material forming the first light-emitting layer EL1 formed on the first bank layer BN1 may be spaced apart from the material forming the first light-emitting layer EL1 formed on the anode electrode AE. For example, the first light-emitting layer EL1 may include two portions disposed on the first bank layer BN1 and the anode electrode AE, and the portions of the first light-emitting layer may be spaced apart from each other. Accordingly, the first light-emitting layer EL1 formed on the first bank layer BN1 and an organic pattern EP may include a same material.

The first cathode electrode CE1 may be formed on the first light-emitting layer EL1. In the process (e.g., the forming of the first cathode electrode CE1), the first cathode electrode CE1 may be formed through a thermal evaporation process or a sputtering deposition process. The forming of the first cathode electrode CE1 may be performed without a separate fine metal mask and may have a higher step coverage than the deposition process of the forming of the first light-emitting layer EL1. Accordingly, the material forming the first cathode electrode CE1 may cover (e.g., entirely cover) the material forming the first light-emitting layer EL1.

In the process (e.g., the forming of the first cathode electrode CE1), the material forming the first cathode electrode CE1 may be formed on the first anode electrode AE1, the second anode electrode AE2, the third anode electrode AE3, and the first bank layer BN1.

In the process (e.g., the forming of the first cathode electrode CE1), the material forming the first cathode electrode CE1 formed on the first bank layer BN1 may be spaced apart from the material forming the first cathode electrode CE1 formed on the anode electrode AE. For example, the first cathode electrode CE1 may include two portions disposed on the first bank layer BN1 and the anode electrode AE, and the portions of the first cathode electrode CE1 may be spaced apart from each other. Accordingly, the material forming the first cathode electrode CE1 formed on the first bank layer BN1 and an electrode pattern CP may include a same material. The electrode pattern CP may cover (e.g., entirely cover) the organic pattern EP.

The first auxiliary electrode AX1 may be formed on the first cathode electrode CE1. In the process (e.g., the forming of the first auxiliary electrode AX1), the first auxiliary electrode AX1 may be formed through a sputtering deposition process. The forming of the first auxiliary electrode AX1 may be performed without a separate fine metal mask and may have a higher step coverage than the deposition process of forming the first cathode electrode CE1. Accordingly, the material forming the first auxiliary electrode AX1 may cover (e.g., entirely cover) the material forming the first cathode electrode CE1.

In the process (e.g., the forming of the first auxiliary electrode AX1), the material forming the first auxiliary electrode AX1 may be formed on the first anode electrode AE1, the second anode electrode AE2, the third anode electrode AE3, and the first bank layer BN1.

In the process (e.g., the forming of the first auxiliary electrode AX1), the material forming the first auxiliary electrode AX1 formed on the first bank layer BN1 may be spaced apart from the material forming the first auxiliary electrode AX1 formed on the anode electrode AE. For example, the first auxiliary electrode AX1 may include two portions disposed on the first bank layer BN1 and the anode electrode AE, and the portions of the first auxiliary electrode AX1 may be spaced apart from each other. Accordingly, the first auxiliary electrode AX1 formed on the first bank layer BN1 and an auxiliary electrode pattern AP may include a same material. The auxiliary electrode pattern AP may cover (e.g., entirely cover) the electrode pattern CP.

In the process (e.g., the forming of the first auxiliary electrode AX1), the first auxiliary electrode AX1 may be in contact with the tip TIP of the third bank layer BN3. The display panel 410 of an embodiment may increase the contact area between the first auxiliary electrode AX1 and the third bank layer BN3 by manufacturing the tip TIP of the third bank layer BN3 to be inclined toward the pixel defining layer PDL. For example, the tip TIP of the third bank layer BN3 may be inclined toward the pixel defining layer PDL, and the contact area between the first auxiliary electrode AX1 and the third bank layer BN3. Thus, resistance between the first auxiliary electrode AX1 and the third bank layer BN3 may be decreased.

The first encapsulation layer TFE1 may be formed on the first auxiliary electrode AX1. The first encapsulation layer TFE1 may cover (e.g., entirely cover) the first anode electrode AE1, the second anode electrode AE2, and the third anode electrode AE3. The first encapsulation layer TFE1 may cover (e.g., also entirely cover) the organic pattern EP, the electrode pattern CP, and the auxiliary electrode pattern AP.

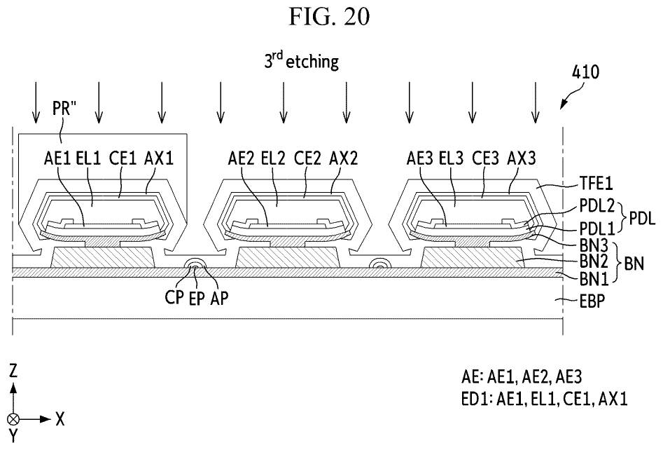

Referring to FIGS. 20 to 22, photoresist PR″ may be formed on the first anode electrode AE1 (e.g., on a portion of the first light-emitting element ED1 overlapping the first anode electrode AE1) and a peripheral portion of the first light-emitting element ED1 (e.g., a portion adjacent to the first anode electrode AE1), and a third etching process (3^{rd} etching) may be performed using the photoresist PR″ as a mask.

In the process (e.g., the third etching process), portions of a material forming the first light-emitting layer EL1 that does not overlap the photoresist PR″ in a plan view, a material forming the first cathode electrode CE1, a material forming the first auxiliary electrode AX1, and a material forming the first encapsulation layer TFE1 may be collectively removed. For example, the first light-emitting element ED1 and the first inorganic layer TFE1l may be formed in the form illustrated in FIG. 5.

In the process (e.g., the third etching process), the second anode electrode AE2 and the third anode electrode AE3 may be exposed again, and the organic pattern EP, the electrode pattern CP, and the auxiliary electrode pattern AP may be removed.

The same process may be repeated to form the second light-emitting layer EL2, the second cathode electrode CE2, the second auxiliary electrode AX2, and the first encapsulation layer TFE1 on the second anode electrode AE2. Thus, the second light-emitting element ED2 and the second inorganic layer TFE12 may be formed. The third light-emitting layer EL3, the third cathode electrode CE3, the third auxiliary electrode AX3, and the first encapsulation layer TFE1 may be formed on the third anode electrode AE3. Therefore, the third light-emitting element ED3 and the third inorganic layer TFE13 may be formed. Detailed description of the same or similar constituent elements is omitted.

For example, the light-emitting element layer EML illustrated in FIG. 4 may be formed. The display panel 410 of an embodiment may increase the contact area between the auxiliary electrode AX and the third bank layer BN3 by including the tip TIP of the third bank layer BN3 inclined toward the pixel defining layer PDL. Thus, the electrical resistance of the display panel 410 may be lowered.

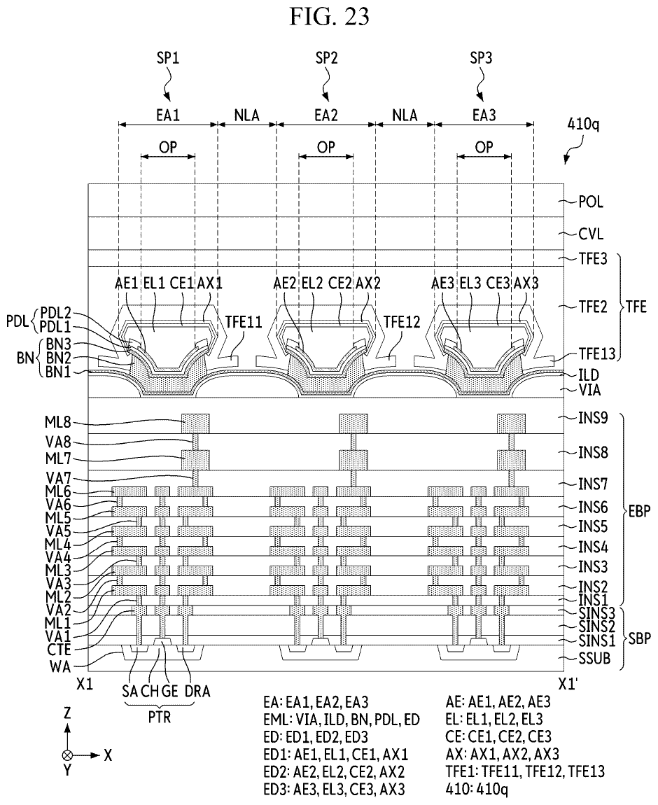

FIG. 23 is a schematic cross-sectional view of a display panel according to an embodiment taken along line X1-X1′ in FIG. 4.

In FIG. 23, detailed description of the same or similar constituent elements is omitted.

The light-emitting element layer EML of the display panel 410q may include a via layer VIA, an element insulating layer ILD, the bank layer BN, the pixel defining layer PDL, and the light-emitting element ED.

The via layer VIA of the display panel 410q may be disposed on the ninth interlayer insulating film INS9 in the non-emission area NLA (e.g., on a portion of the ninth interlayer insulating film INS9 overlapping the non-emission area NLA in a plan view). The via layer VIA may be positioned in the emission area EA (e.g., on a portion of the ninth interlayer insulating film INS9 overlapping the emission area EA in a plan view). Multiple via layers VIA may be formed on the ninth interlayer insulating film INS9, and the via layers VIA may be spaced apart from each other. Each of the via layers VIA may have a convex shape in the third direction (e.g., the Z-axis direction).

The via layer VIA may assist a portion of the bank layer BN and a portion of the pixel defining layer PDL to be inclined toward the third direction (e.g., the Z-axis direction). For example, the vial layer VIA may increase the inclination of the bank layer BN and the pixel defining layer PDL in the third direction (e.g., the Z-axis direction). Detailed description of the same or similar constituent elements is omitted.

The via layer VIA may include an organic material. As an example, the via layer VIA may include at least one of acrylic resin, epoxy resin, polyamide resin, polyimide resin, unsaturated polyester resin, polyphenylene resin, polyphenylenesulfide resin, and benzocyclobutene. However, the disclosure is not limited thereto.

The element insulating layer ILD of the display panel 410q may be disposed on the ninth interlayer insulating film INS9 in the emission area EA (e.g., on a portion of the ninth interlayer insulating film INS9 overlapping the emission area EA and the non-emission area NLA in a plan view). The element insulating layer ILD may cover (e.g., entirely cover) the via layers VIA.

The element insulating layer ILD may assist in preventing the lower structure (e.g., the via layer VIA) from lifting or preventing out-gas due to the via layer VIA from permeating into the light-emitting element ED. For example, the element insulating layer ILD may prevent the lifting of the via layer VIA and out-gas of the via layer VIA toward the light-emitting element ED.

The element insulating layer ILD may include an inorganic insulating material. As an example, the element insulating layer ILD may include at least one of silicon oxide, silicon nitride, and silicon oxynitride. However, the disclosure is not limited thereto.

The bank layer BN of the display panel 410q may be disposed on the element insulating layer ILD. The bank layer BN may have a protrusion toward the non-emission area NLA. Thus, the bank layer BN may have an undercut shape.

The bank layer BN may include the first bank layer BN1, the second bank layer BN2, and the third bank layer BN3.

The first bank layer BN1 of the display panel 410q may be positioned on the element insulating layer ILD in the emission area EA and the non-emission area NLA (e.g., on a portion of the element insulating layer ILD overlapping the emission area EA and the non-emission area NLA in a plan view). The first bank layer BN1 may cover (e.g., entirely cover) the element insulating layer ILD.

The first bank layer BN1 may electrically connect the first to third cathode electrodes CE1, CE2, and CE3 to each other, which are spaced apart from each other in the first to third emission areas EA1, EA2, and EA3.

The first bank layer BN1 may include a conductive metal having etching resistance. As an example, the first bank layer BN1 may be titanium (Ti).

The first bank layer BN1 may cover the lower structure (e.g., the via layer VIA and the ninth interlayer insulating film INS9) along the profile of the via layer VIA and the ninth interlayer insulating film INS9. Accordingly, the first bank layer BN1 may have a convex shape toward the third direction (e.g., the Z-axis direction) as the first bank layer BN1 is positioned further toward the non-emission area NLA. For example, in case that the distance between the first bank layer BN1 and the non-emission area NLA is decreased, the degree of convex shape of the first bank layer BN1 in the third direction (e.g., the Z-axis direction) may be increased.

The second bank layer BN2 of the display panel 410q may be positioned on the first bank layer BN1 in the emission area EA (e.g., on a portion of the first bank layer BN1 overlapping the emission area EA in a plan view). The second bank layer BN2 may not overlap the non-emission area NLA in a plan view. The second bank layer BN2 may be electrically connected to the first bank layer BN1.

The second bank layer BN2 may include a metal with high electrical conductivity. As an example, the second bank layer BN2 may include aluminum (Al).

The second bank layer BN2 may cover the first bank layer BN1 along a profile (e.g., a profile of the first bank layer BN1). Accordingly, the second bank layer BN2 may have a shape that is inclined in the third direction (e.g., the Z-axis direction) as the second bank layer BN2 is positioned further toward the non-emission area NLA. For example, in case that the distance between the second bank layer BN2 and the non-emission area NLA is decreased, and the inclination of the second bank layer BN2 in the third direction (e.g., the Z-axis direction) may be increased.

The third bank layer BN3 of the display panel 410q may be positioned on the second bank layer BN2 in the emission area EA (e.g., on a portion of the second bank layer BN2 overlapping the emission area EA in a plan view). The third bank layer BN3 may not overlap the non-emission area NLA in a plan view. The third bank layer BN3 may be electrically connected to the second bank layer BN2.

The third bank layer BN3 may include a conductive metal having etching resistance. As an example, the third bank layer BN3 may be titanium (Ti).

The third bank layer BN3 may cover the second bank layer BN2 along a profile (e.g., a profile of the second bank layer BN2). Accordingly, the second bank layer BN2 may have a shape that is inclined in the third direction (e.g., the Z-axis direction) as the second bank layer BN2 is positioned further toward the non-emission area NLA. For example, in case that the distance between the second bank layer BN2 and the non-emission area NLA is decreased, and the inclination of the second bank layer BN2 in the third direction (e.g., the Z-axis direction) may be increased.

The detailed description of the bank layer BN is provided below.

The pixel defining layer PDL of the display panel 410q may be positioned on the bank layer BN in the emission area EA (e.g., on a portion of the bank layer BN overlapping the emission area EA in a plan view). The pixel defining layer PDL may not overlap the non-emission area NLA in a plan view. The pixel defining layer PDL may include the first pixel defining layer PDL1 and the second pixel defining layer PDL2 sequentially stacked each other.

The first pixel defining layer PDL1 of the display panel 410q may cover the bank layer BN along a profile (e.g., a profile of the bank layer BN). Accordingly, the first pixel defining layer PDL1 may have a shape that is inclined in the third direction (e.g., the Z-axis direction) as the first pixel defining layer PDL1 is positioned further toward the non-emission area NLA. For example, in case that the distance between the first pixel defining layer PDL1 and the non-emission area NLA is decreased, the inclination of the first pixel defining layer PDL1 in the third direction (e.g., the Z-axis direction) may be increased.

The second pixel defining layer PDL2 of the display panel 410q may be positioned on the first pixel defining layer PDL1 and the anode electrode AE. The second pixel defining layer PDL2 may define the opening OP and may expose a portion of the anode electrode AE in the opening OP.

The second pixel defining layer PDL2 of the display panel 410q may cover the lower structure (e.g., the bank layer BN) along the profile of the bank layer BN. Accordingly, the second pixel defining layer PDL2 may have a shape that is inclined in the third direction (e.g., the Z-axis direction) as the second pixel defining layer PDL2 is positioned further toward the non-emission area NLA. For example, in case that the distance between the second pixel defining layer PDL2 and the non-emission area NLA is decreased, the inclination of the second pixel defining layer PDL2 in the third direction (e.g., the Z-axis direction) may be increased.

Since the light-emitting element ED included in the display panel 410q and the light-emitting element ED included in the display panel 410 have a same structure and feature, detailed description of the same or similar constituent elements is omitted.

The first encapsulation layer TFE1 included in the display panel 410q may be spaced apart from the first bank layer BN1 in the third direction (e.g., the Z-axis direction). Detailed description of the first encapsulation layer TFEL is provided below.

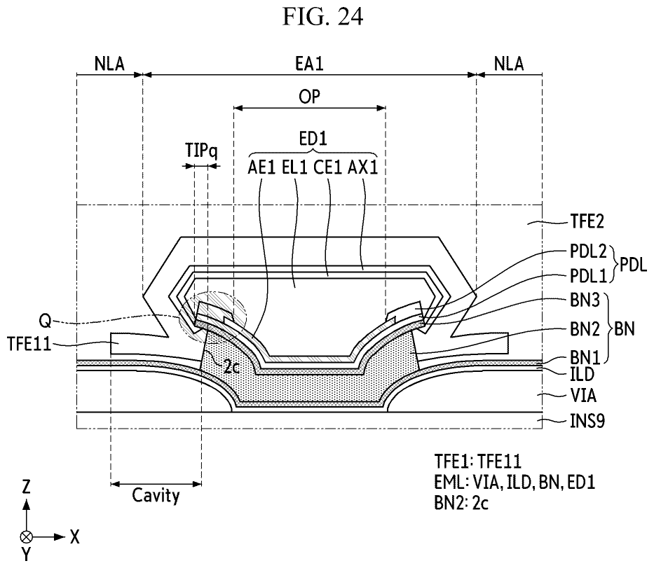

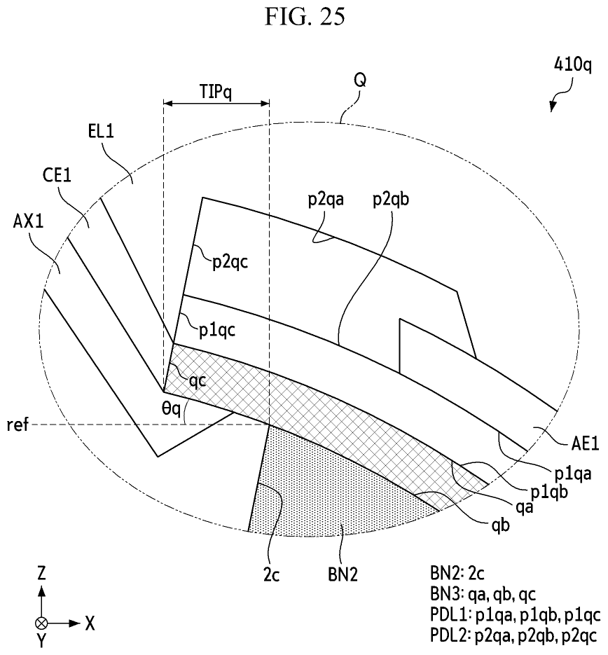

FIG. 24 is a schematic enlarged cross-sectional view of the light-emitting element layer overlapping the first emission area in FIG. 23 in a plan view, and FIG. 25 is a schematic enlarged cross-sectional view of area Q in FIG. 24.

Referring to FIGS. 24 and 25, the light-emitting element layer EML of the display panel 410q (e.g., refer to FIG. 23) may include the via layer VIA, the element insulating layer ILD, the bank layer BN, the pixel defining layer PDL, and the first light-emitting element ED1 disposed in the first emission area EA1 (e.g., on a portion of the bank layer BN overlapping the first emission area EA1 in a plan view).

The second bank layer BN2 of the display panel 410q may be positioned in contact with and on the first bank layer BN1. The second bank layer BN2 may cover the lower structure (e.g., the via layer VIA and the ninth interlayer insulating film INS9) along the profile of the via layer VIA and the ninth interlayer insulating film INS9 disposed below the second bank layer BN2. Accordingly, the second bank layer BN2 may have an inclined surface inclined toward the third direction (e.g., the Z-axis direction) as the second bank layer BN2 is positioned closer to the non-emission area NLA. For example, in case that the distance between the second bank layer BN2 and the non-emission area NLA is decreased, the inclination of the second bank layer BN2 in the third direction (e.g., the Z-axis direction) may be increased.

The second bank layer BN2 may include the side surface 2c. The side surface 2c of the second bank layer BN2 may be a side facing the non-emission area NLA.

In some embodiments, a portion (e.g., an upper portion) of the side surface 2c of the second bank layer BN2 may be in contact with the first inorganic layer TFE11, and another portion (e.g., a lower portion) of the side surface 2c of the second bank layer BN2 may be in contact with the second encapsulation layer TFE2. However, the specification is not limited thereto, and the side surface 2c of the second bank layer BN2 may not be in contact with the second encapsulation layer TFE2.

The third bank layer BN3 of the display panel 410q may be positioned in contact with and on the second bank layer BN2. The third bank layer BN3 may cover the lower structure (e.g., the second bank layer BN2) along the profile of the via layer VIA and the ninth interlayer insulating film INS9 disposed below the third bank layer BN3. Accordingly, the third bank layer BN3 may have an inclined surface inclined toward the third direction (e.g., the Z-axis direction) as the third bank layer BN3 is positioned closer to the non-emission area NLA. For example, in case that the distance between the third bank layer BN3 and the non-emission area NLA is decreased, the inclination of the third bank layer BN3 in the third direction (e.g., the Z-axis direction) may be increased.

In some embodiments, the third bank layer BN3 may include a first surface qa, a second surface qb, and a side surface qc. The first surface qa may face the first pixel defining layer PDL1, the second surface qb may be opposite to the first surface qa, and the side surface qc may be a surface connecting the first surface qa and the second surface qb. For example, the side surface qc may extend from the first surface qa to the second surface qb.

The first surface qa and the second surface qb of the third bank layer BN3 may be curved surfaces. For example, the first surface qa and the second surface qb may have inclined surfaces inclined toward the third direction (e.g., the Z-axis direction) as the first surface qa and the second surface qb are positioned closer to the non-emission area NLA. For example, the distance between the first surface qa (or the second surface qb) and the non-emission area NLA is decreased, the inclination of the first surface qa (or the second surface qb) in the third direction (e.g., the Z-axis direction) may be increased.

The side surface qc of the third bank layer BN3 may protrude further in a direction toward the non-emission area NLA than the side surface 2c of the second bank layer BN2. For example, the third bank layer BN3 may have a tip TIPq that protrudes further in a direction toward the non-emission area NLA than the side surface 2c of the second bank layer BN2. An undercut may be formed between the tip TIPq of the third bank layer BN3 and the side surface 2c of the second bank layer BN2.

The tip TIPq of the third bank layer BN3 may be formed by different etch ratios of materials included in the second bank layer BN2 and the third bank layer BN3 during the manufacturing process of the display panel 410q. Detailed description of the manufacturing process is provided below.

The tip TIPq of the third bank layer BN3 included in the display panel 410q may have a shape inclined to the third direction (e.g., the Z-axis direction) as the tip TIPq is positioned further toward the non-emission area NLA. For example, the tip TIPq of the third bank layer BN3 may be inclined toward the third direction (e.g., the Z-axis direction) as the tip TIPq is positioned further toward the non-emission area NLA. For example, in case that the distance between the tip TIPq and the non-emission area NLA is decreased, the inclination of the tip TIPq of the third bank layer BN3 may be increased.

In some embodiments, the tip TIPq of the third bank layer BN3 may be a curved surface inclined to the third direction (e.g., the Z-axis direction) by a second inclination angle θq with respect to the horizontal reference line ref extending in parallel in the first direction (e.g., the X-axis direction). As an example, the second inclination angle θq may have a value of about 0.1 degrees or greater and about 60 degrees or smaller. For example, the second inclination angle θq may be in a range of about 0.1 degrees to about 60 degrees.

The first pixel defining layer PDL1 of the display panel 410q may be positioned in contact with and on the third bank layer BN3. The first pixel defining layer PDL1 may cover (e.g., entirely cover) the first surface qa of the third bank layer BN3 and may not be in contact with the side surface qc of the third bank layer BN3.

In some embodiments, the first pixel defining layer PDL1 may include a first surface p1qa, a second surface p1qb, and a side surface p1qc. The first surface p1qa may face the second pixel defining layer PDL2, the second surface p1qb may be a surface opposite to the first surface p1qa, and the side surface p1qc may be a surface connecting the first surface p1qa and the second surface p1qb. For example, the side surface p1qc may extend from the first surface p1qa to the second surface p1qb.

The first surface p1qa and the second surface p1qb of the first pixel defining layer PDL1 may be curved surfaces. For example, the first surface p1qa and the second surface p1qb may have inclined surfaces inclined toward the third direction (e.g., the Z-axis direction) as the first surface p1qa and the second surface p1qb are positioned closer to the non-emission area NLA. For example, the distance between the first surface p1qa (or the second surface p1qb) and the non-emission area NLA is decreased, the inclination of the first surface p1qa (or the second surface p1qb) in the third direction (e.g., the Z-axis direction) may be increased.

In some embodiments, the side surface p1qc of the first pixel defining layer PDL1 may be positioned on a same virtual line as the side surface qc of the third bank layer BN3, but the disclosure is not limited thereto.

The second pixel defining layer PDL2 of the display panel 410q may surround the opening OP and expose the first anode electrode AE1. The second pixel defining layer PDL2 may be in contact with the first pixel defining layer PDL1 and the first anode electrode AE1.

In some embodiments, the second pixel defining layer PDL2 may include a first surface p2qa, a second surface p2qb, and a side surface p2qc. The second surface p2qb may face the first pixel defining layer PDL1, the first surface p2qa may be a surface opposite to the second surface p2qb, and the side surface p2qc may be a surface connecting the first surface p2qa and the second surface p2qb. For example, the side surface p2qc may extend from the first surface p2qa to the second surface p2qb.

The first surface p2qa and the second surface p2qb of the second pixel defining layer PDL2 may be curved surfaces. For example, the first surface p2qa and the second surface p2qb may have inclined surfaces inclined toward the third direction (e.g., the Z-axis direction) as the first surface p2qa and the second surface p2qb are positioned closer to the non-emission area NLA. For example, the distance between the first surface p2qa (or the second surface p2qb) and the non-emission area NLA is decreased, the inclination of the first surface p2qa (or the second surface p2qb) in the third direction (e.g., the Z-axis direction) may be increased.

In some embodiments, the side surface p2qc of the second pixel defining layer PDL2 and the side surface qc of the third bank layer BN3 may be positioned on a same virtual line, but the disclosure is not limited thereto.

The first light-emitting layer EL1 of the display panel 410q may be in contact with the pixel defining layer PDL and the first anode electrode AE1. For example, the first light-emitting layer EL1 may cover (e.g., completely cover) the second pixel defining layer PDL2 and may cover a portion of the first pixel defining layer PDL1. For example, the first light-emitting layer EL1 may be in contact with the side surface p1qc of the first pixel defining layer PDL1 and the side surface p2qc of the second pixel defining layer PDL2.

The first cathode electrode CE1 of the display panel 410q may be in contact with and cover (e.g., be entirely in contact with and entirely cover) the first light-emitting layer EL1. The first cathode electrode CE1 may cover (e.g., completely cover) the side surface p1qc of the first pixel defining layer PDL1 and the side surface p2qc of the second pixel defining layer PDL2.

The first auxiliary electrode AX1 of the display panel 410q may be in contact with and cover (e.g., be entirely in contact with and entirely cover) the first cathode electrode CE1. As described above, the first cathode electrode CE1 may be electrically connected to the bank layer BN through the first auxiliary electrode AX1.

The display panel 410q may include a shape in which the tip TIPq of the third bank layer BN3 is inclined to the third direction (e.g., the Z-axis direction). Thus, the first auxiliary electrode AX1 may cover the tip TIPq of the third bank layer BN3. For example, the first auxiliary electrode AX1 may be in contact with and cover a portion of the second surface qb of the third bank layer BN3 on the tip TIPq of the third bank layer BN3 (e.g., on a portion overlapping the tip TIPq of the third bank layer BN3 in a plan view). For example, the display panel 410q may increase the contact area between the first auxiliary electrode AX1 and the third bank layer BN3, so that an electrical contact defect between the first cathode electrode CE1 and the third bank layer BN3 may be solved. For example, the contact defect between the first cathode electrode CE1 and the third bank layer BN3 may be prevented, and the electrical resistance of the display panel 410q may be decreased.

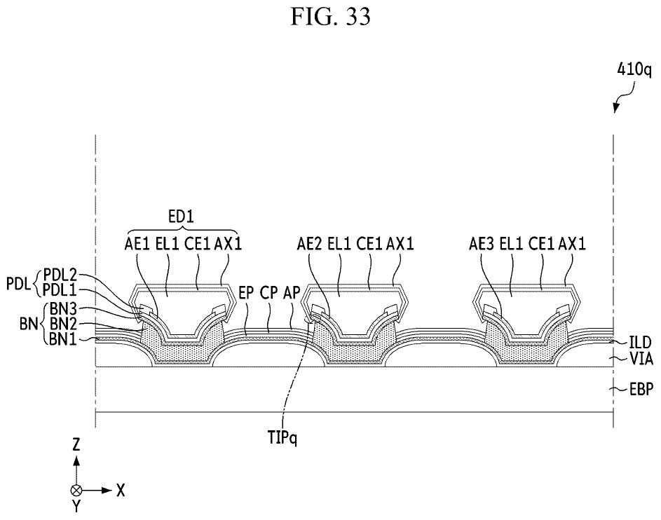

The first inorganic layer TFE1l of the display panel 410q may be spaced apart from the first bank layer BN1 in the third direction (e.g., the Z-axis direction). For example, the first inorganic layer TFE11 and the first bank layer BN1 may be spaced apart from each other in the third direction (e.g., the Z-axis direction) with the cavity disposed (e.g., interposed) between the first inorganic layer TFE11 and the first bank layer BN1. The cavity may be caused during the manufacturing process in which the organic pattern EP (e.g., refer to FIG. 33), the electrode pattern CP (e.g., refer to FIG. 33), and the auxiliary electrode pattern AP (e.g., refer to FIG. 33) are positioned between the first encapsulation layer TFEL and the first bank layer BN1 and removed by a subsequent process. Accordingly, the cavity may be the basis (or an evidence) for forming the first light-emitting element ED1 without a separate fine metal mask during the manufacturing process of the display panel 410q. Detailed description of the manufacturing process is provided below.

The second encapsulation layer TFE2 of the display panel 410q may be positioned in contact with and on the first inorganic layer TFE11. The stepped portion formed by the first inorganic layer TFE11 and the cavity positioned between the first inorganic layer TFE11 and the first bank layer BN1 may be filled by the second encapsulation layer TFE2.

For simplicity of description, the light-emitting element layer EML overlapping the first emission area EA1 of the display panel 410q in a plan view and the light-emitting element layers EML overlapping the second emission area EA2 and the third emission area EA3 in a plan view may have a same structure and feature.

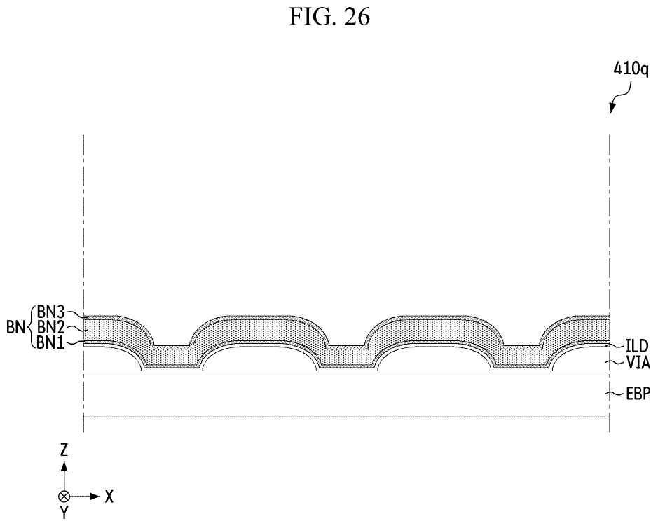

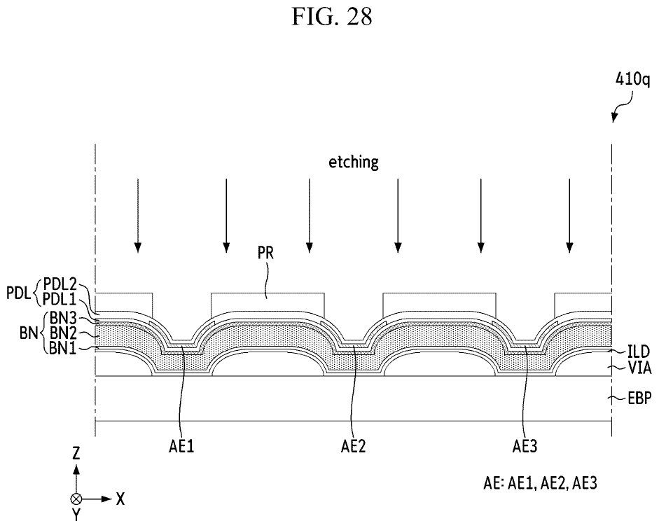

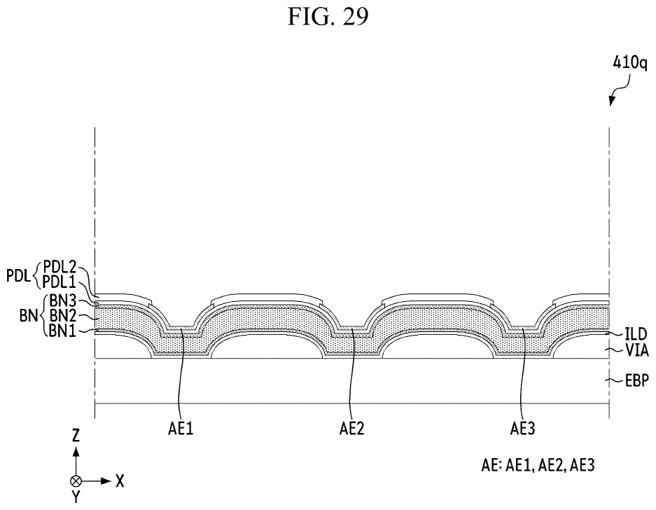

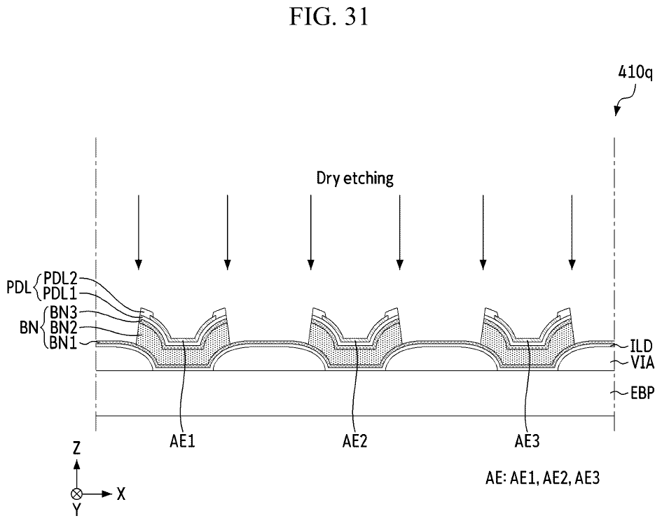

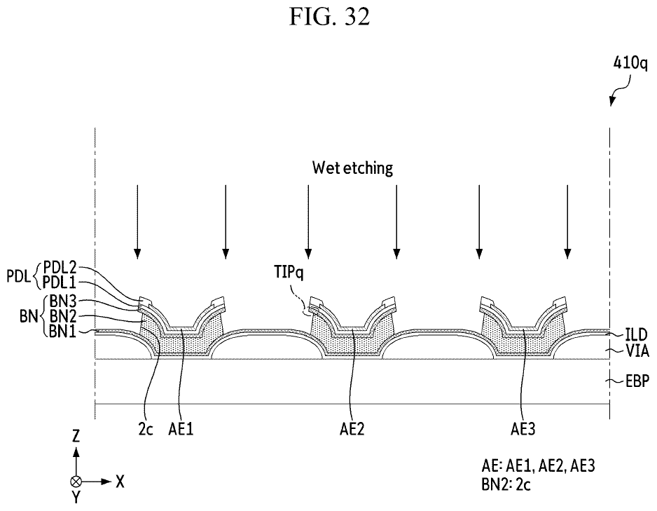

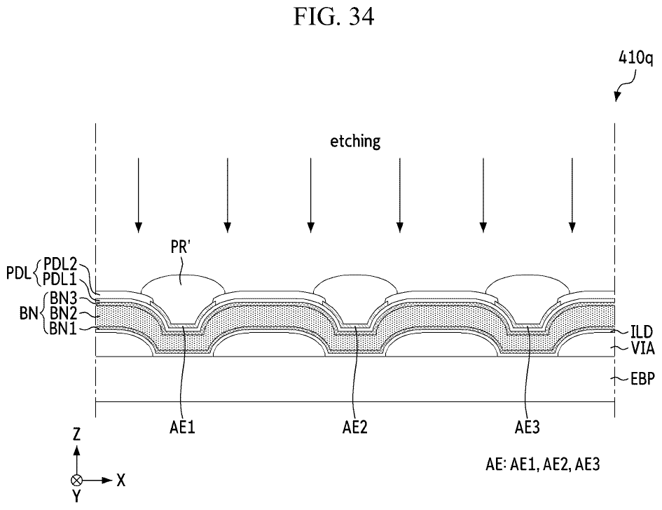

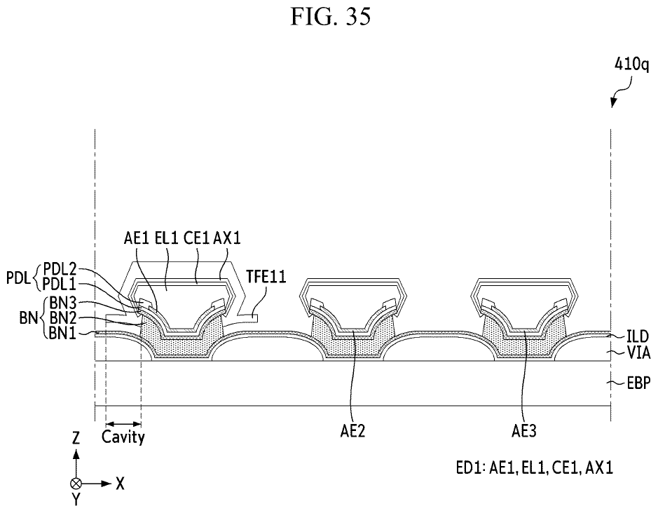

FIGS. 26 to 36 are schematic cross-sectional views sequentially illustrating a manufacturing process of the light-emitting element layer of the display panel of FIG. 23. Hereinafter, detailed description of the manufacturing process of the light-emitting element layer of FIG. 23 is provided with respect to the formation order of each layer.

Referring to FIG. 26, after patterning the via layers VIA on the light-emitting element backplane EBP, the element insulating layer ILD may cover (e.g., entirely cover) the via layers VIA. The structure of the light-emitting element backplane EBP is the same as described above with reference to FIG. 23. Detailed description of the same or similar constituent elements is omitted.

The bank layer BN may be formed on the element insulating layer ILD. The bank layer BN may include the first bank layer BN1, the second bank layer BN2, and the third bank layer BN3 sequentially stacked in the third direction (e.g., the Z-axis direction).

In the process (e.g., the forming of the bank layer BN), the first bank layer BN1, the second bank layer BN2, and the third bank layer BN3 may cover (e.g., entirely cover) the element insulating layer ILD. The first bank layer BN1, the second bank layer BN2, and the third bank layer BN3 may cover the lower structure (e.g., the via layers VIA) along the shapes of the via layers VIA positioned below the third bank layer BN3. Accordingly, the first bank layer BN1, the second bank layer BN2, and the third bank layer BN3 may have convexly curved surfaces toward the third direction (e.g., the Z-axis direction).

The materials of the first bank layer BN1, the second bank layer BN2, and the third bank layer BN3 have already been described, and detailed description of the same or similar constituent elements is omitted.

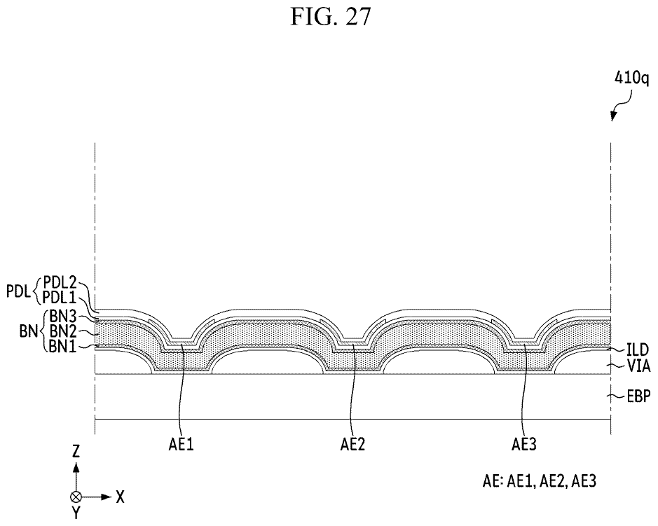

Referring to FIGS. 27 to 29, the pixel defining layer PDL and the anode electrode AE may be formed on the bank layer BN. The pixel defining layer PDL may include the first pixel defining layer PDL1 and the second pixel defining layer PDL2. The first pixel defining layer PDL1 may be formed on (e.g., be entirely formed on) the third bank layer BN3. The second pixel defining layer PDL2 may cover (e.g., entirely cover) anode electrodes AE and may be positioned on the first pixel defining layer PDL1.

In the process (e.g., the forming the pixel defining layer PDL and the anode electrodes AE), the first pixel defining layer PDL1 and the second pixel defining layer PDL2 may cover the lower structure (e.g., the bank layer BN) along the shapes of the via layers VIA positioned below the pixel defining layer PDL. Accordingly, in the process (e.g., the forming the pixel defining layer PDL and the anode electrodes AE), the first pixel defining layer PDL1 and the second pixel defining layer PDL2 may have convexly curved surfaces toward the third direction (e.g., the Z-axis direction).

In the process (e.g., the forming the pixel defining layer PDL and the anode electrodes AE), the anode electrodes AE may be positioned on the first pixel defining layer PDL1. The anode electrode AE may include the first anode electrode AE1, the second anode electrode AE2, and the third anode electrode AE3. The first anode electrode AE1, the second anode electrode AE2, and the third anode electrode AE3 may be spaced apart from each other.

The photoresists PR may be formed on the second pixel defining layer PDL2. The photoresists PR may be spaced apart from each other and may expose a portion of the anode electrode AE. An etching process may be performed using the photoresists PR as a mask. For example, the etching process may be performed as a dry etching process.

In the process (e.g., the forming the pixel defining layer PDL and the anode electrodes AE), a portion of the second pixel defining layer PDL2 overlapping the anode electrode AE in a plan view may be removed. Thus, the first anode electrode AE1, the second anode electrode AE2, and the third anode electrode AE3 may be exposed.

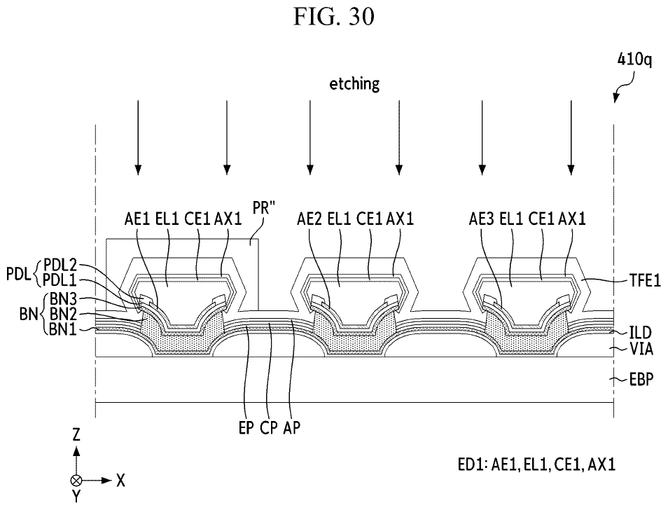

Referring to FIGS. 30 to 32, photoresist PR′ may be formed on a portion of the second pixel defining layer PDL2 overlapping the anode electrode AE in a plan view, and an etching process may be performed again. The photoresists PR′ may be spaced apart from each other and may cover (e.g., entirely cover) the anode electrode AE. For example, the etching process in the process may be performed alternately as a dry etching process and a wet etching process. Portions of the second bank layer BN2, the third bank layer BN3, and the pixel defining layer PDL may be removed through the process (e.g., the etching process).

For example, a dry etching process may be first performed to remove portions of the second bank layer BN2, the third bank layer BN3, the first pixel defining layer PDL1, and the second pixel defining layer PDL2. In the process (e.g., the dry etching process), portions of the pixel defining layer PDL, the second bank layer BN2, and the third bank layer BN3 may be isotropically removed. For example, through the process (e.g., the dry etching process), the pixel defining layer PDL, the second bank layer BN2, and the third bank layer BN3 may have side surfaces positioned on a same virtual line.

A wet etching process may be performed. In the process (e.g., the wet etching process), the second bank layer BN2 and the third bank layer BN3 including different materials may be different in etch selectivity. For example, the second bank layer BN2 may include a material having a higher etching rate than the third bank layer BN3 with respect to the etching solution used in the wet etching process. Accordingly, in the process (e.g., the wet etching process), the second bank layer BN2 may be recessed further in the first direction (e.g., the X-axis direction) than the third bank layer BN3, and the third bank layer BN3 may have the tip TIPq that protrudes further than the side surface 2c of the second bank layer BN2.

In the process (e.g., the wet etching process), the tip TIPq of the third bank layer BN3, the first pixel defining layer PDL1, and the second pixel defining layer PDL2 may have shapes inclined toward the third direction (e.g., the Z-axis direction). For example, in the process (e.g., the wet etching process), the tip TIPq of the third bank layer BN3, the first pixel defining layer PDL1, and the second pixel defining layer PDL2 may have shapes inclined in the same manner as the profile of the via layer VIA disposed below the tip TIPq of the third bank layer BN3, the first pixel defining layer PDL1, and the second pixel defining layer PDL2.

Referring to FIGS. 33 to 35, the first light-emitting element ED1 may be formed by depositing the first light-emitting layer EL1, the first cathode electrode CE1, and the first auxiliary electrode AX1 on the first anode electrode AE1.

The first light-emitting layer EL1 may be formed through a thermal evaporation process. In the process (e.g., the forming of the first light-emitting element ED1), the forming of the first light-emitting layer EL1 may be performed without using a separate fine metal mask. Accordingly, the material forming the first light-emitting layer EL1 may be formed on the first anode electrode AE1, the second anode electrode AE2, the third anode electrode AE3, and the first bank layer BN1.

In the process (e.g., the forming of the first light-emitting element ED1), the material forming the first light-emitting layer EL1 formed on the first bank layer BN1 may be spaced apart from the material forming the first light-emitting layer EL1 formed on the anode electrode AE. For example, the first light-emitting layer EL1 may include two portions disposed on the first bank layer BN1 and the anode electrode AE, and the portions of the first light-emitting layer EL1 may be spaced apart from each other. Accordingly, the material forming the first light-emitting layer EL1 formed on the first bank layer BN1 and the organic pattern EP may include a same material.

The first cathode electrode CE1 may be formed on the first light-emitting layer EL1. In the process (e.g., the forming of the first cathode electrode CE1), the first cathode electrode CE1 may be formed through a thermal evaporation process or a sputtering deposition process. The forming of the first cathode electrode CE1 may be performed without a separate fine metal mask and may have a higher step coverage than the deposition process of forming the first light-emitting layer EL1. Accordingly, the material forming the first cathode electrode CE1 may cover (e.g., entirely cover) the material forming the first light-emitting layer EL1.

In the process (e.g., the forming of the first cathode electrode CE1), the material forming the first cathode electrode CE1 may be formed on the first anode electrode AE1, the second anode electrode AE2, the third anode electrode AE3, and the first bank layer BN1.

In the process (e.g., the forming of the first cathode electrode CE1), the material forming the first cathode electrode CE1 formed on the first bank layer BN1 may be spaced apart from the material forming the first cathode electrode CE1 formed on the anode electrode AE. For example, the first cathode electrode CE1 may include two portions on the first bank layer BN1 and the anode electrode AE, and the portions of the first cathode electrode CE1 may be spaced apart from each other. Accordingly, the first cathode electrode CE1 formed on the first bank layer BN1 and the electrode pattern CP may include a same material. The electrode pattern CP may cover (e.g., entirely cover) the organic pattern EP.

The first auxiliary electrode AX1 may be formed on the first cathode electrode CE1. In the process (e.g., the forming of the first auxiliary electrode AX1), the first auxiliary electrode AX1 may be formed through a sputtering deposition process. The process of forming the first auxiliary electrode AX1 may be performed without a separate fine metal mask and may have a higher step coverage than the deposition process of forming the first cathode electrode CE1. Accordingly, the material forming the first auxiliary electrode AX1 may cover (e.g., entirely cover) the material forming the first cathode electrode CE1.

In the process (e.g., the forming of the first auxiliary electrode AX1), the material forming the first auxiliary electrode AX1 may be formed on the first anode electrode AE1, the second anode electrode AE2, the third anode electrode AE3, and the first bank layer BN1.

In the process (e.g., the forming of the first auxiliary electrode AX1), the material forming the first auxiliary electrode AX1 formed on the first bank layer BN1 may be spaced apart from the material forming the first auxiliary electrode AX1 formed on the anode electrode AE. For example, the first auxiliary electrode AX1 may include two portions disposed on the first bank layer BN1 and the anode electrode AE, and the portions of the first auxiliary electrode AX1 may be spaced apart from each other. Accordingly, the first auxiliary electrode AX1 formed on the first bank layer BN1 and the auxiliary electrode pattern AP may include a same material. The auxiliary electrode pattern AP may cover (e.g., entirely cover) the electrode pattern CP.

In the process (e.g., the forming of the first auxiliary electrode AX1), the material forming the first auxiliary electrode AX1 may cover the tip TIPq of the third bank layer BN3. In the display panel 410q, the tip TIPq of the third bank layer BN3 may have an inclined surface inclined toward the third direction (e.g., the Z-axis direction). Thus, the contact area between the first auxiliary electrode AX1 and the third bank layer BN3 may be increased. Detailed description of the same or similar constituent elements is omitted.

The first encapsulation layer TFE1 may be formed on the first auxiliary electrode AX1. The first encapsulation layer TFE1 may cover (e.g., entirely cover) the first anode electrode AE1, the second anode electrode AE2, and the third anode electrode AE3. The first encapsulation layer TFE1 may cover (e.g., also entirely cover) the organic pattern EP, the electrode pattern CP, and the auxiliary electrode pattern AP.

Photoresists PR″ may be formed on the first encapsulation layer TFE1 (e.g., on a portion of the first encapsulation layer TFE1 overlapping the first anode electrode AE1) and a peripheral portion of the first light-emitting element ED1 of FIG. 33 (e.g., a portion adjacent to the first anode electrode AE1), and an etching process may be performed using the photoresist PR″ as a mask.

In the process (e.g., the etching process), portions of a material forming the first light-emitting layer EL1 that does not overlap the photoresist PR″ in a plan view, a material forming the first cathode electrode CE1, a material forming the first auxiliary electrode AX1, and a material forming the first encapsulation layer TFE1 may be collectively removed. Accordingly, the first encapsulation layer TFE1 may be formed in the form of the first inorganic layer TFE11.

In the process (e.g., the etching process), the second anode electrode AE2 and the third anode electrode AE3 may be exposed again, and the organic pattern EP, the electrode pattern CP, and the auxiliary electrode pattern AP may be removed. The cavity may be formed in a portion in which the organic pattern EP, the electrode pattern CP, and the auxiliary electrode pattern AP have been removed. Accordingly, the first bank layer BN1 and the first inorganic layer TFE1l may be spaced apart from each other in the third direction (e.g., the Z-axis direction) with the cavity disposed (e.g., interposed) between the first bank layer BN1 and the first inorganic layer TFE11.

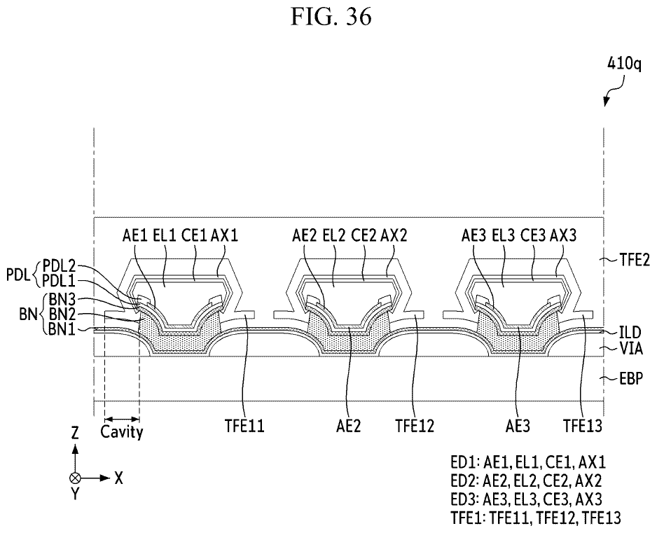

Referring to FIG. 36, a same process as the above-described process of forming the first light-emitting element ED1 may be repeated to form the second light-emitting layer EL2, the second cathode electrode CE2, the second auxiliary electrode AX2, and the first encapsulation layer TFE1 on the second anode electrode AE2. Thus, the second light-emitting element ED2 and the second inorganic layer TFE12 may be formed in the second emission area EA2 (e.g., refer to FIG. 23). The third light-emitting layer EL3, the third cathode electrode CE3, the third auxiliary electrode AX3, and the first encapsulation layer TFE1 may be formed on the third anode electrode AE3. Thus, the third light-emitting element ED3 and the third inorganic layer TFE13 may be formed in the third emission area EA3 (e.g., refer to FIG. 23).

The light-emitting element layer EML of the display panel 410q illustrated in FIG. 23 may be formed by forming the second encapsulation layer TFE2 on the first encapsulation layer TFE1.

The above description is an example of technical features of the disclosure, and those skilled in the art to which the disclosure pertains will be able to make various modifications and variations. Thus, the embodiments of the disclosure described above may be implemented separately or in combination with each other.

Therefore, the embodiments disclosed in the disclosure are not intended to limit the technical spirit of the disclosure, but to describe the technical spirit of the disclosure, and the scope of the technical spirit of the disclosure is not limited by these embodiments. The protection scope of the disclosure should be interpreted by the following claims, and it should be interpreted that all technical spirits within the equivalent scope are included in the scope of the disclosure.

What is claimed is:

1. A display device comprising:
a bank layer disposed on an emission area of a substrate and comprising at least one metal layer;
a pixel defining layer disposed on the bank layer and defining an opening; and
a light-emitting element disposed on the pixel defining layer and comprising a light-emitting layer, a cathode electrode, and an auxiliary electrode, wherein
the bank layer comprises:
a first side surface facing a non-emission area of the substrate; and
a tip portion protruding further toward the non-emission area than the first side surface, and
a portion of the tip portion of the bank layer facing the non-emission area is inclined in a direction intersecting the substrate.

2. The display device of claim 1, wherein
the pixel defining layer overlaps the emission area in a plan view, and
a portion of the pixel defining layer in contact with the tip portion of the bank layer is inclined in the direction intersecting the substrate.

3. The display device of claim 2, wherein
the tip portion of the bank layer comprises:
a first surface in contact with the pixel defining layer;
a second surface opposite to the first surface; and
a second side surface connecting the first surface and the second surface, and
the second surface is inclined by a first angle with respect to a reference line parallel to the substrate.

4. The display device of claim 3, wherein the first angle is greater than or equal to about 0.1 degrees.

5. The display device of claim 4, wherein a height of the tip portion of the bank layer is less than or equal to about 2000 angstroms.

6. The display device of claim 3, wherein
the auxiliary electrode entirely covers the cathode electrode, and
the auxiliary electrode is in contact with the second surface and the second side surface of the bank layer.

7. The display device of claim 6, wherein the cathode electrode is electrically connected to the bank layer by the auxiliary electrode.

8. The display device of claim 6, wherein the auxiliary electrode covers the tip portion of the bank layer.

9. The display device of claim 1, wherein
the bank layer comprises a first bank layer, a second bank layer, and a third bank layer which are sequentially stacked, and
the second bank layer and the third bank layer contain different materials from each other.

10. The display device of claim 9, wherein
the second bank layer contains aluminum, and
the third bank layer contains titanium.

11. The display device of claim 10, wherein the third bank layer comprises a tip portion protruding further toward the non-emission area than the second bank layer.

12. The display device of claim 1, wherein the pixel defining layer comprises:
a first pixel defining layer in contact with the bank layer; and
a second pixel defining layer disposed on the first pixel defining layer and defining the opening.

13. The display device of claim 12, wherein
the first pixel defining layer comprises:
a first surface in contact with the second pixel defining layer; and
a second surface opposite to the first surface, and
in a portion of the first pixel defining layer overlapping the tip portion of the bank layer in a plan view, portions of the first surface and the second surface are inclined in the direction intersecting the substrate.

14. The display device of claim 13, wherein the light-emitting layer completely covers the second pixel defining layer and is in contact with a portion of the first pixel defining layer.

15. The display device of claim 2, further comprising:
an encapsulation layer disposed on the light-emitting element,
wherein
the encapsulation layer is in contact with the bank layer, and
the encapsulation layer fills an undercut portion formed by the first side surface of the bank layer and the tip portion of the bank layer.

16. The display device of claim 1, further comprising:
a via layer disposed between the substrate and the bank layer, wherein
the via layer has a convex shape in the direction intersecting the substrate,
the bank layer and the pixel defining layer cover a lower structure along a shape of the via layer, and
the bank layer overlaps the via layer in the direction intersecting the substrate.

17. A method for manufacturing a display device, comprising:
forming a plurality of sacrificial layers on a substrate;
forming a bank layer covering the plurality of sacrificial layers and a first pixel defining layer covering the bank layer;
forming an anode electrode on the first pixel defining layer;
forming a second pixel defining layer covering an edge of the anode electrode;
removing the second pixel defining layer, the first pixel defining layer, the bank layer not overlapping the anode electrode in a plan view, and the plurality of sacrificial layers; and
forming a light-emitting layer, a cathode electrode, and an auxiliary electrode on the anode electrode, wherein
in the removing of the sacrificial layer, the bank layer is formed with a tip portion protruding further than a side surface of the bank layer, and
an edge of the tip portion of the bank layer is inclined toward the first pixel defining layer.

18. The method of claim 17, wherein in the removing of the sacrificial layer, an edge of the first pixel defining layer and the bank layer are inclined in a same direction.

19. The method of claim 18, wherein
in the forming of the first pixel defining layer, the first pixel defining layer has tensile stress, and
in the forming of the light-emitting layer, the light-emitting layer is formed by a photo-pattern process.

20. An electronic device comprising:
at least one display device comprising a substrate comprising an emission area and a non-emission area; and
a display device housing accommodating the at least one display device, wherein
the at least one display device comprises:
a bank layer disposed on the emission area of the substrate and comprising at least one metal layer;
a pixel defining layer disposed on the bank layer and defining an opening; and
a light-emitting element disposed on the pixel defining layer and comprising a light-emitting layer, a cathode electrode, and an auxiliary electrode,
the bank layer comprises:
a first side surface facing the non-emission area; and
a tip portion protruding further toward the non-emission area than the first side surface, and
a portion of the tip portion of the bank layer facing the non-emission area is inclined in a direction intersecting the substrate.
